(19) United States
(12) Patent Application Publication
(10) Pub. No.: US 2026/0020272 A1
(43) Pub. Date: Jan. 15, 2026

(54) STRUCTURE AND FORMATION METHOD OF SEMICONDUCTOR DEVICE WITH EPITAXIAL STRUCTURE

(71) Applicant: Taiwan Semiconductor Manufacturing Company, Ltd., Hsinchu (TW)

(72) Inventors: Ta-Chun LIN, Hsinchu (TW); Jhon-Jhy LIAW, Zhudong Township (TW)

(21) Appl. No.: 18/769,614

(22) Filed: Jul. 11, 2024

(51) Int. Cl. H01L 29/66; H01L 21/02; H01L 21/285; H01L 29/06; H01L 29/08; H01L 29/423; H01L 29/45; H01L 29/775; H01L 29/786

(52) U.S. Cl. CPC H10D 30/014; H01L 21/02532; H01L 21/02579; H01L 21/28518; H10D 30/43; H10D 30/6735; H10D 30/6757; H10D 62/121; H10D 62/151; H10D 64/018; H10D 64/62

(57) ABSTRACT

A semiconductor device structure and a formation method are provided. The method includes forming multiple sacrificial layers and multiple semiconductor layers laid out in an alternating manner on a substrate. The method also includes partially removing the sacrificial layers and the semiconductor layers to form a recess exposing side edges of the sacrificial layers and the semiconductor layers. The method further includes forming p-type doped epitaxial structures on the side edges of the semiconductor layers and forming a germanium-containing epitaxial structure wrapped around the p-type doped epitaxial structures. The germanium-containing epitaxial structure has a higher atomic concentration of germanium than that of the p-type doped epitaxial structures. In addition, the method includes removing the sacrificial layers to release multiple semiconductor nanostructures constructed by remaining portions of the semiconductor layers and forming a metal gate stack wrapped around each of the semiconductor nanostructures.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1B are top views of various stages of a process for forming a portion of a semiconductor device structure, in accordance with some embodiments.

FIGS. 2A-2D are cross-sectional views of various stages of a process for forming a portion of a semiconductor device structure, in accordance with some embodiments.

FIGS. 3A-3Q are cross-sectional views of various stages of a process for forming portions of a semiconductor device structure, in accordance with some embodiments.

FIGS. 4A-4C are cross-sectional views of various stages of a process for forming portions of a semiconductor device structure, in accordance with some embodiments.

FIGS. 5A-5C are cross-sectional views of various stages of a process for forming portions of a semiconductor device structure, in accordance with some embodiments.

FIG. 6 is a cross-sectional view of portions of a semiconductor device structure, in accordance with some embodiments.

FIG. 7A is a cross-sectional view of portions of a semiconductor device structure, in accordance with some embodiments.

FIG. 7B is a top view of portions of a semiconductor device structure, in accordance with some embodiments.

FIG. 8 is a cross-sectional view of portions of a semiconductor device structure, in accordance with some embodiments.

FIG. 9A is a cross-sectional view of a portion of a semiconductor device structure, in accordance with some embodiments.

FIG. 9B is a cross-sectional view of a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100% of what is specified. Furthermore, terms such as “substantially parallel” or “substantially perpendicular” are to be interpreted as not to exclude insignificant deviation from the specified arrangement and may include for example deviations of up to 10 degrees in some embodiments. The word “substantially” does not exclude “completely” e.g. a composition which is “substantially free” from Y may be completely free from Y in some embodiments.

Terms such as “about” in conjunction with a specific distance or size are to be interpreted so as not to exclude insignificant deviation from the specified distance or size and may include for example deviations of up to 10% of what is specified in some embodiments. The term “about” in relation to a numerical value x may mean x±5 or 10% of what is specified in some embodiments.

Embodiments of the disclosure may relate to FinFET structure having fins. The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using one or more other applicable processes.

Embodiments of the disclosure may relate to the gate all around (GAA) transistor structures. The GAA structure may be patterned using any suitable method. For example, the structures may be patterned using one or more photolithography processes, including double-patterning or multi-patterning processes. In some embodiments, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

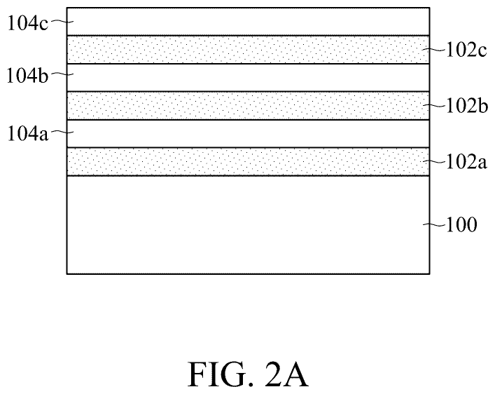

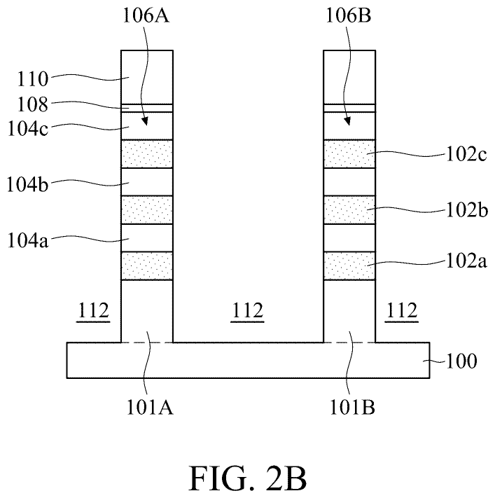

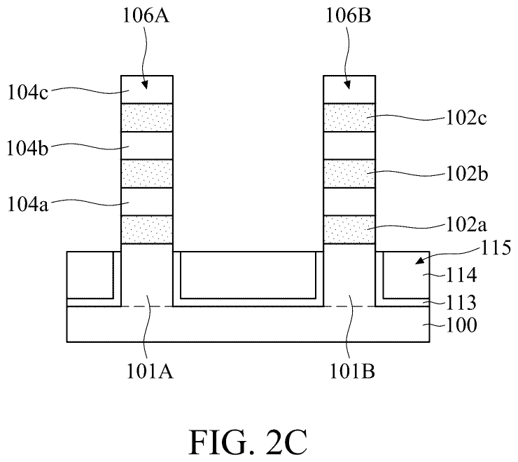

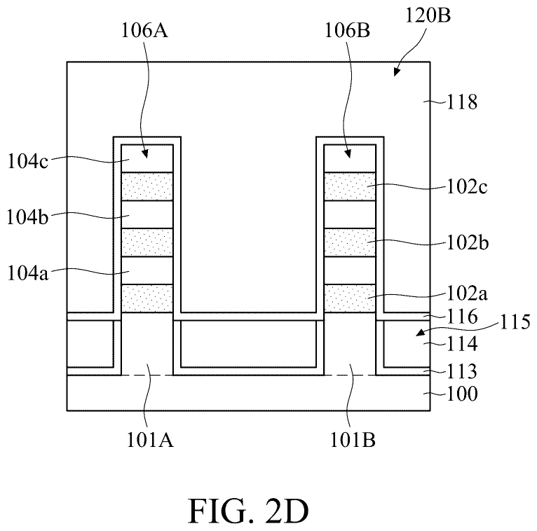

FIGS. 2A-2D are cross-sectional views of various stages of a process for forming a portion of a semiconductor device structure, in accordance with some embodiments. As shown in FIG. 2A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

As shown in FIG. 2A, a semiconductor stack having multiple semiconductor layers is formed over the semiconductor substrate 100, in accordance with some embodiments. In some embodiments, the semiconductor stack includes multiple semiconductor layers 102a, 102b, and 102c. The semiconductor stack also includes multiple semiconductor layers 104a, 104b, and 104c. In some embodiments, the semiconductor layers 102a-102c and the semiconductor layers 104a-104c are laid out in an alternating manner, as shown in FIG. 2A.

In some embodiments, the semiconductor layers 102a-102c function as sacrificial layers that will be removed in a subsequent process to release the semiconductor layers 104a-104c. The semiconductor layers 104a-104c that are released form multiple semiconductor nanostructures. The semiconductor layers 104a-104c may function as the channel structures of one or more transistors.

In some embodiments, the semiconductor layers 104a-104c that will be used to form channel structures are made of a material that is different than that of the semiconductor layers 102a-102c. In some embodiments, the semiconductor layers 104a-104c are made of or include silicon, germanium, other suitable materials, or a combination thereof. In some embodiments, the semiconductor layers 102a-102c are made of or include silicon germanium. In some other embodiments, the semiconductor layers 104a-104c are made of silicon germanium, and the semiconductor layers 102a-102c are made of silicon germanium with different atomic concentration of germanium than that of the semiconductor layers 104a-104c. Due to the different compositions, different etching selectivity and/or different oxidation rates during subsequent processing may be achieved between the semiconductor layers 102a-102c and the semiconductor layers 104a-104c.

The present disclosure contemplates that the semiconductor layers 102a-102c and the semiconductor layers 104a-104c include any combination of semiconductor materials that can provide desired etching selectivity, desired oxidation rate differences, and/or desired performance characteristics (e.g., materials that maximize current flow).

In some embodiments, the semiconductor layers 102a-102c and 104a-104c are formed using multiple epitaxial growth operations. Each of the semiconductor layers 102a-102c and 104a-104c may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the semiconductor layers 102a-102c and 104a-104c are grown in-situ in the same process chamber. In some embodiments, the growth of the semiconductor layers 102a-102c and 104a-104c are alternately and sequentially performed in the same process chamber to complete the formation of the semiconductor stack. In some embodiments, the vacuum of the process chamber is not broken before the epitaxial growth of the semiconductor stack is accomplished.

Afterwards, hard mask elements are formed over the semiconductor stack to assist in a subsequent patterning of the semiconductor stack. Each of the hard mask elements may include a first mask layer 108 and a second mask layer 110. The first mask layer 108 and the second mask layer 110 may be made of different materials. One or more photolithography processes and one or more etching processes are used to pattern the semiconductor stack into multiple fin structures. The fin structures may be patterned by any suitable method. For example, the fin structures may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

The semiconductor stack is partially removed to form multiple fin structures (including fin structures 106A and 106B) and multiple trenches 112, as shown in FIG. 2B. Each of the fin structures 106A-106B may include portions of the semiconductor layers 102a-102c and 104a-104c and multiple semiconductor fins (including semiconductor fins 101A and 101B), as shown in FIG. 2B. The semiconductor substrate 100 may also be partially removed during the etching process that forms the fin structures. Protruding portions of the semiconductor substrate 100 that remain form the semiconductor fins 101A and 101B.

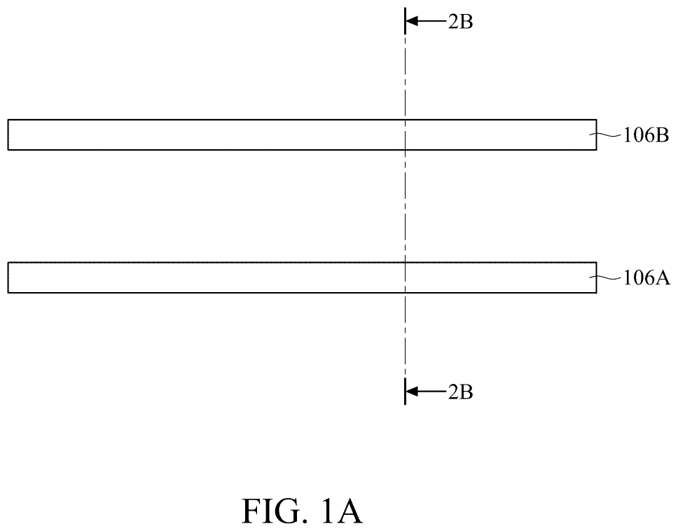

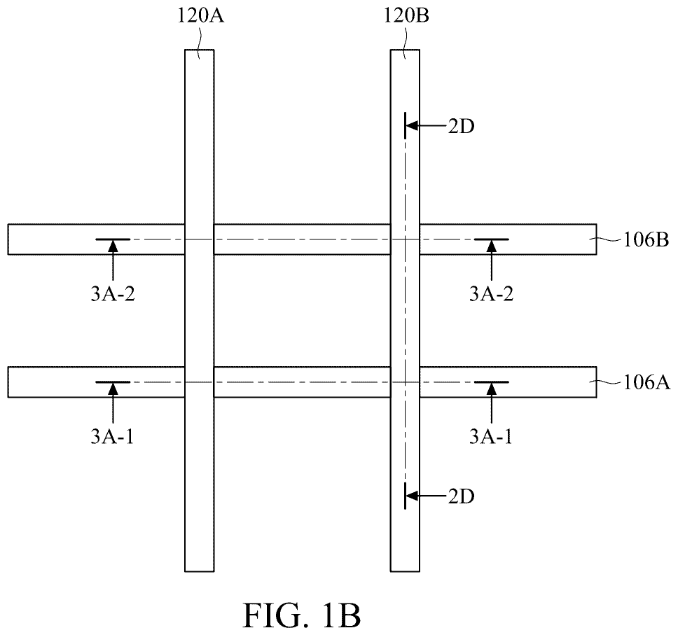

FIGS. 1A-1B are top views of various stages of a process for forming a portion of a semiconductor device structure, in accordance with some embodiments. As shown in FIG. 1A, multiple fin structures 106A and 106B are formed, in accordance with some embodiments. In some embodiments, the fin structures 106A and 106B are oriented lengthwise. In some embodiments, the extending directions of the fin structures 106A and 106B are substantially parallel to each other, as shown in FIG. 1A. In some embodiments, FIG. 2B is a cross-sectional view of the structure taken along the line 2B-2B in FIG. 1A.

Afterwards, as shown in FIG. 2C, an isolation structure 115 is formed to surround lower portions of the fin structures 106A and 106B, in accordance with some embodiments. In some embodiments, the isolation structure 115 includes dielectric fillings 114 and a liner layer 113 that is adjacent to the semiconductor fins 101A and 101B.

In some embodiments, one or more dielectric layers for forming the dielectric fillings 114 are deposited over the fin structures 106A and 106B and the semiconductor substrate 100. The dielectric layers may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof. The liner layer 113 may be made of or include silicon nitride, silicon oxynitride, silicon carbide, silicon oxycarbide, one or more other suitable materials, or a combination thereof. The dielectric layers and the liner layer 113 may be deposited using a flowable chemical vapor deposition (FCVD) process, an atomic layer deposition (ALD) process, a chemical vapor deposition (CVD) process, one or more other applicable processes, or a combination thereof.

Afterwards, a planarization process is used to partially remove the dielectric layers and the liner layer 113. The hard mask elements (including the first mask layer 108 and the second mask layer 110) may also function as a stop layer of the planarization process. The planarization process may include a chemical mechanical polishing (CMP) process, a grinding process, a dry polishing process, an etching process, one or more other applicable processes, or a combination thereof.

Afterwards, one or more etching back processes are used to partially remove the dielectric layers and the liner layer 113. As a result, the remaining portion of the dielectric layers forms the dielectric fillings 114 of the isolation structure 115. Upper portions of the fin structures 106A and 106B protrude from the top surface of the isolation structure 115, as shown in FIG. 2C.

In some embodiments, the etching back process for forming the isolation structure 115 is carefully controlled to ensure that the topmost surface of the isolation structure 115 is positioned at a suitable height level, as shown in FIG. 2C. In some embodiments, the topmost surface of the isolation structure 115 is below the bottommost surface of the semiconductor layer 102a that functions as a sacrificial layer.

Afterwards, the hard mask elements (including the first mask layer 108 and the second mask layer 110) are removed. Alternatively, in some other embodiments, the hard mask elements are removed or consumed during the planarization process and/or the etching back process that forms the isolation structure 115.

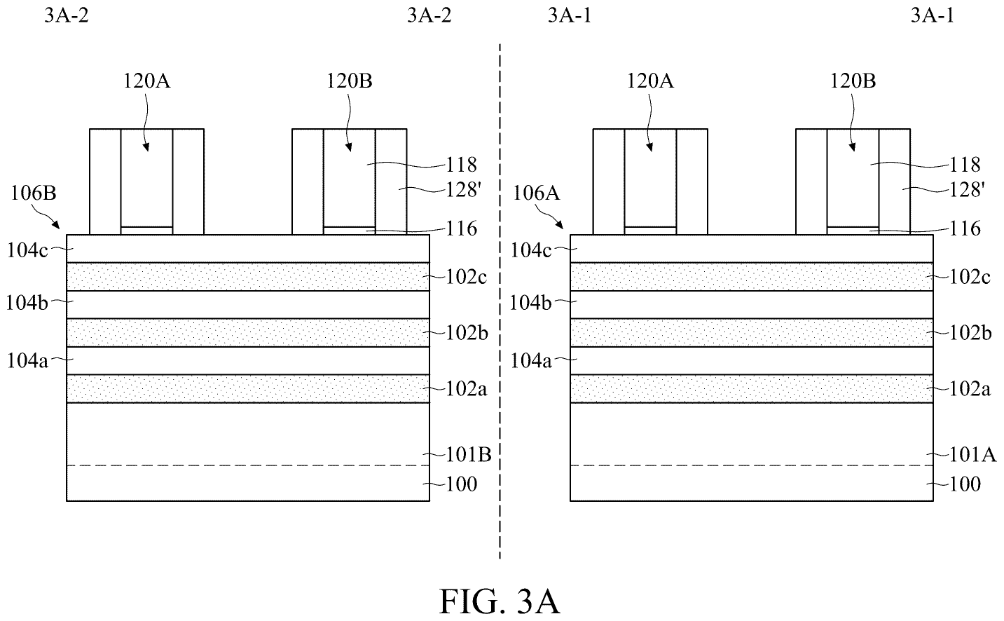

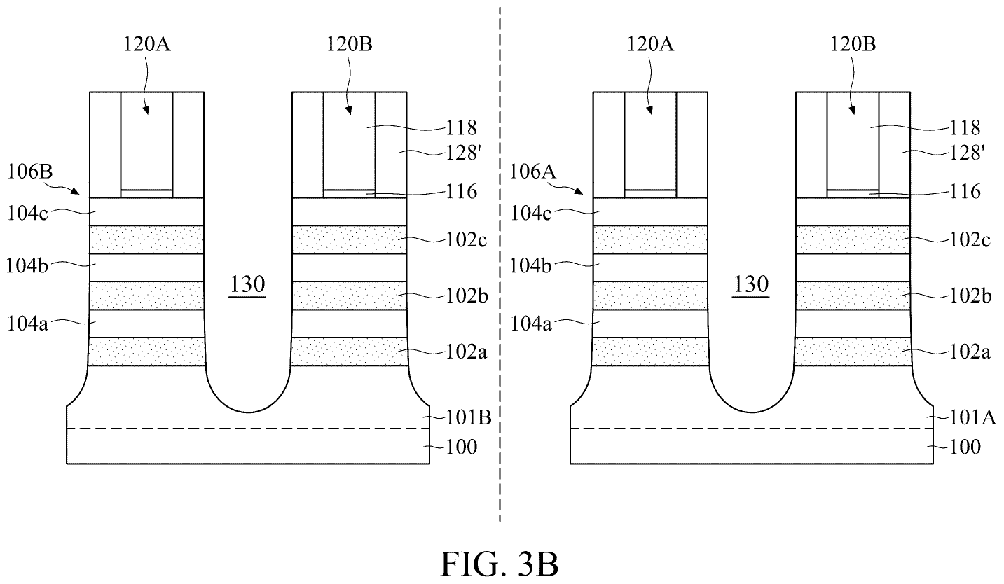

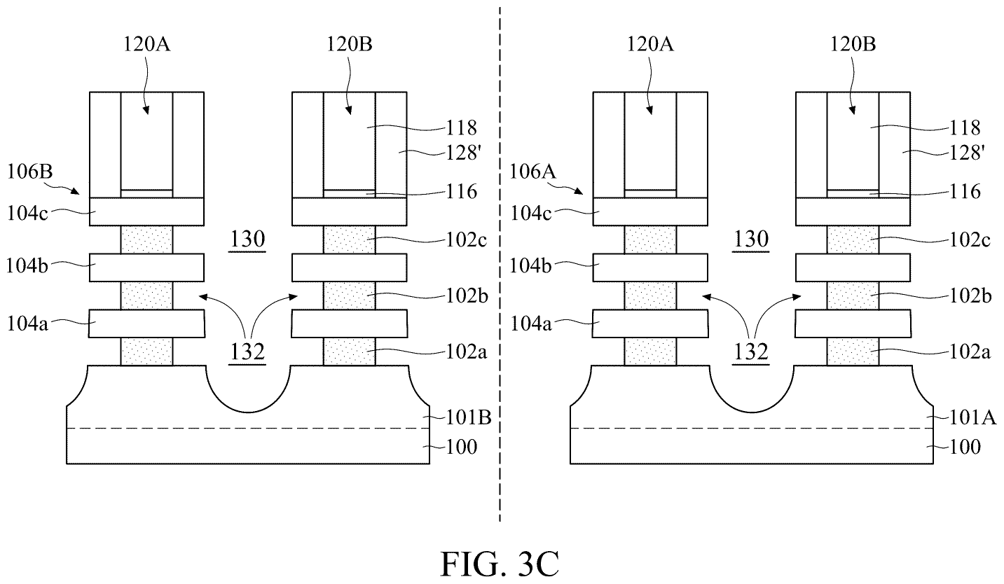

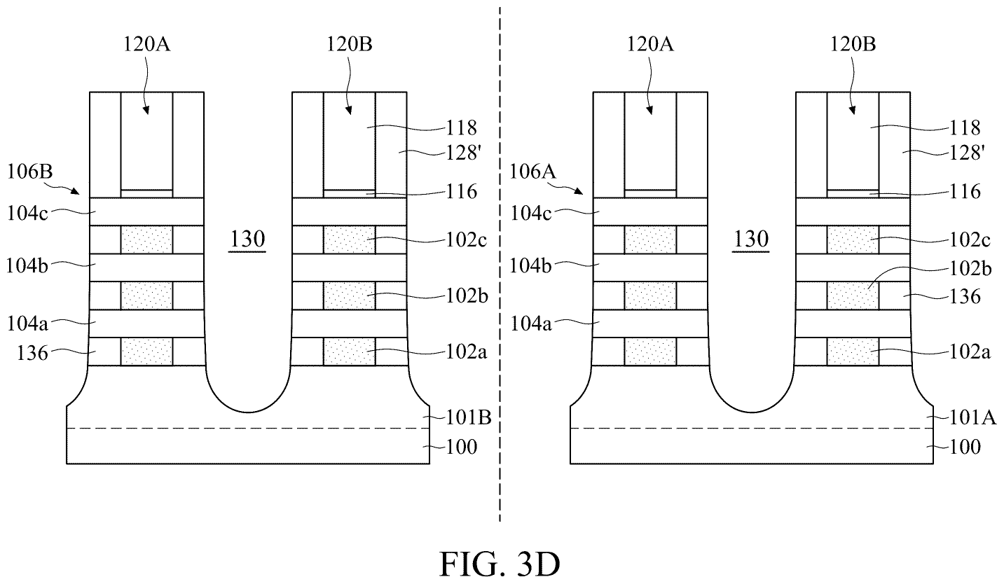

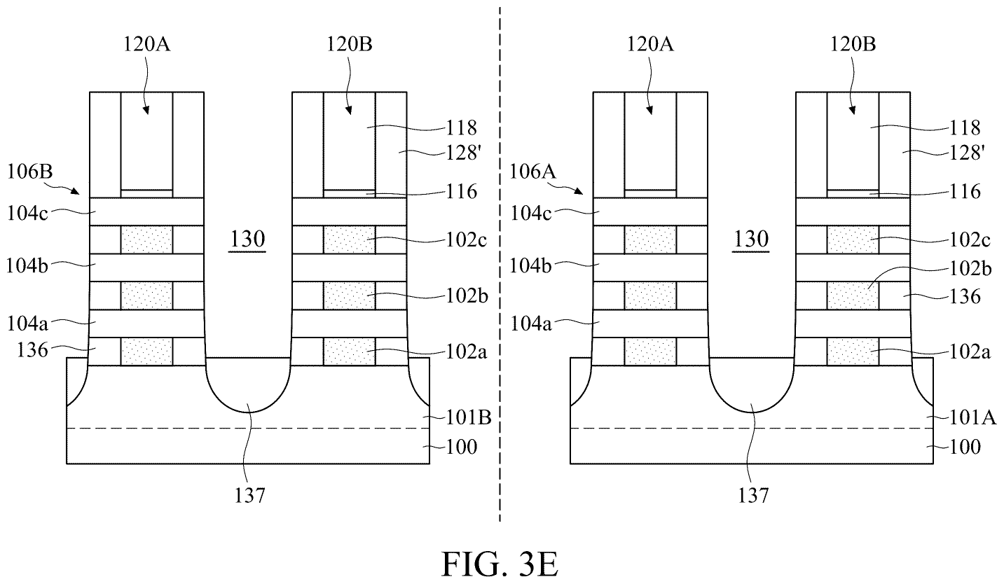

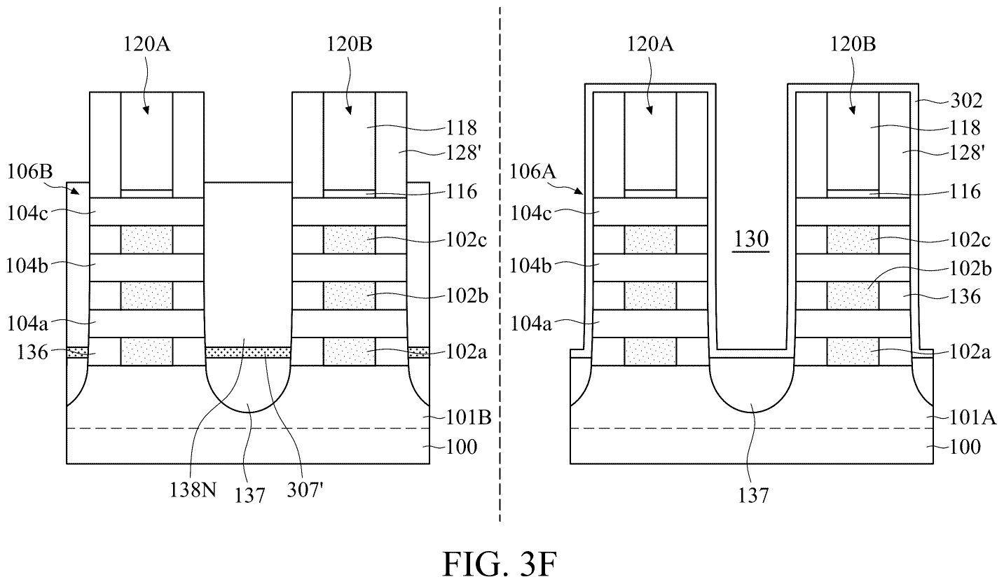

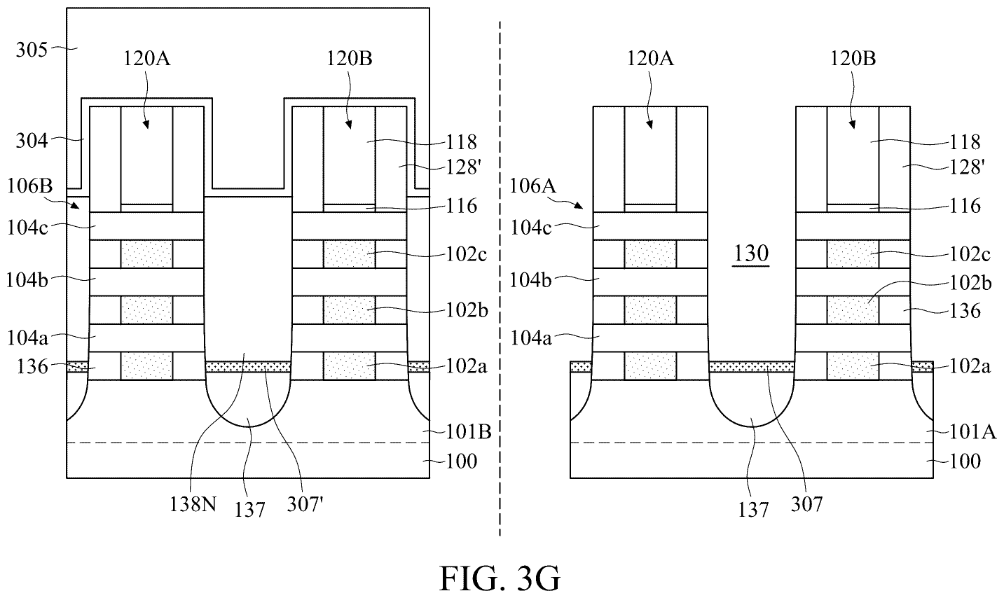

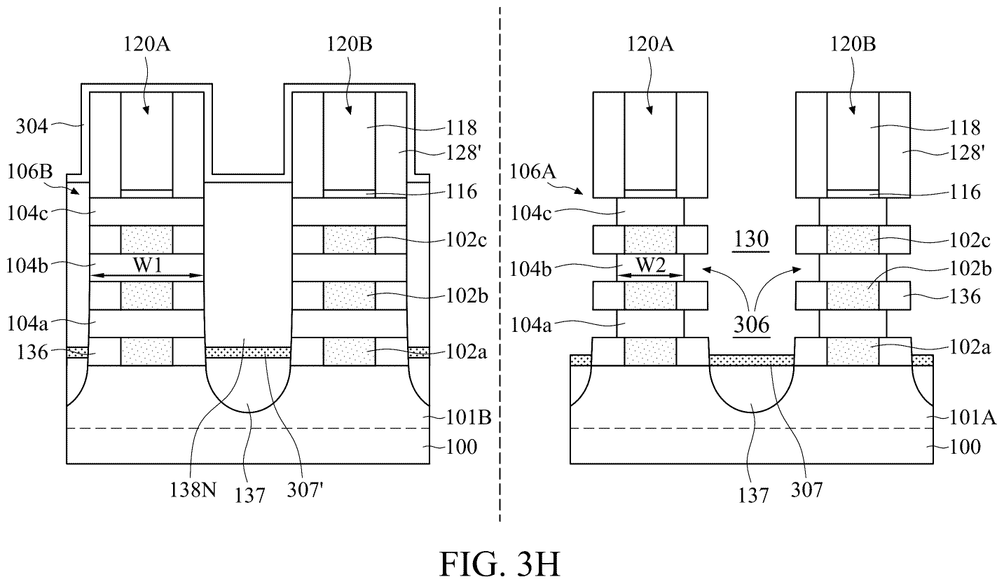

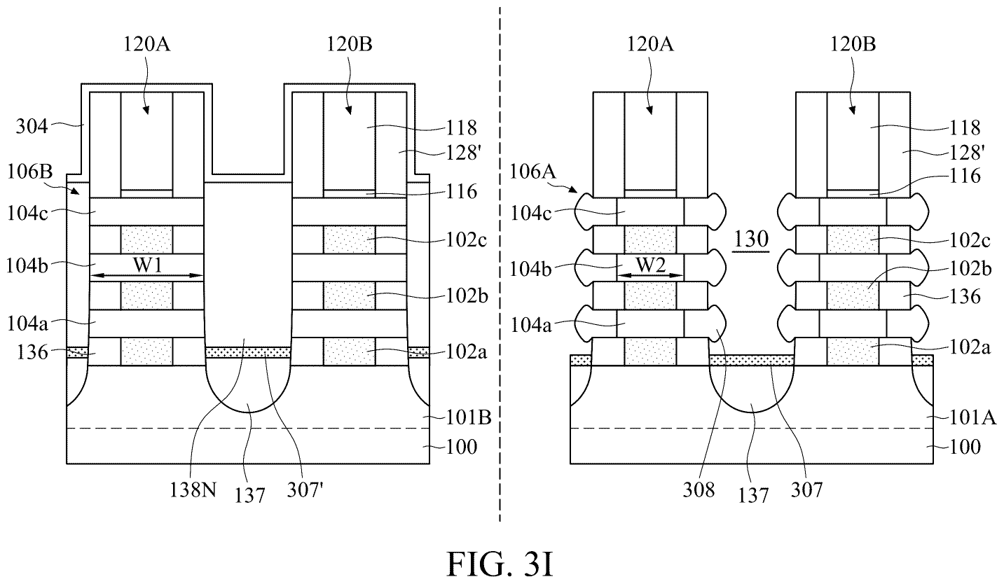

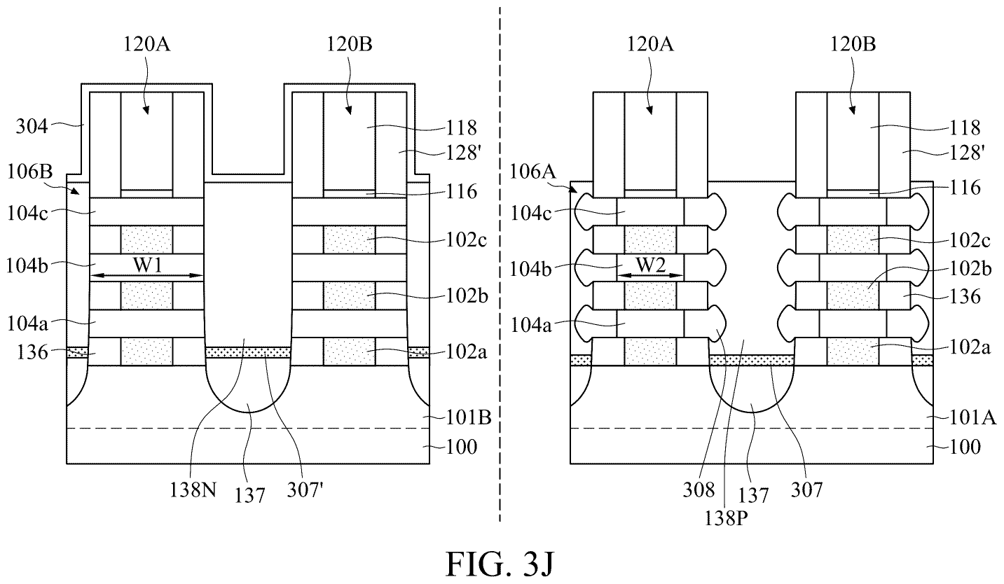

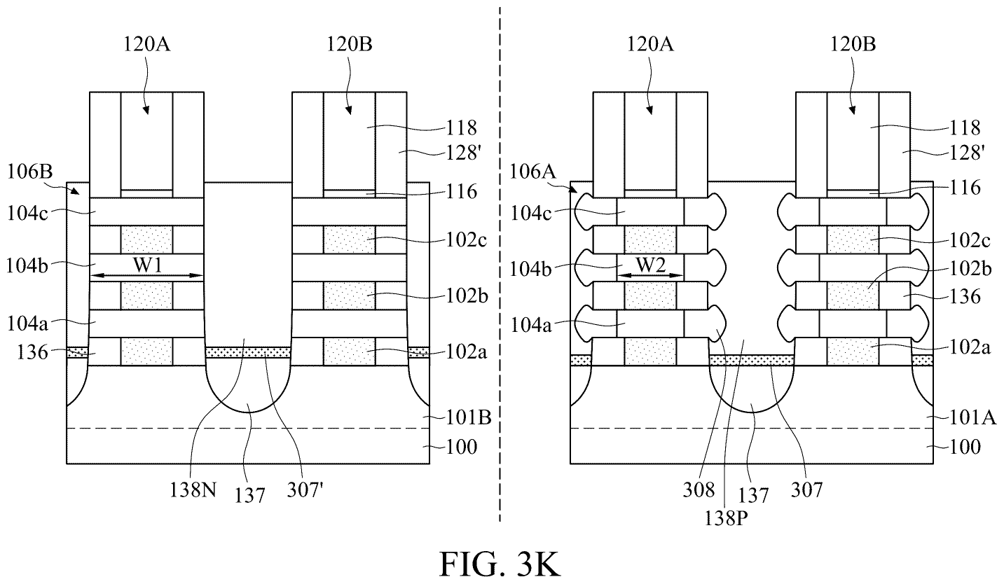

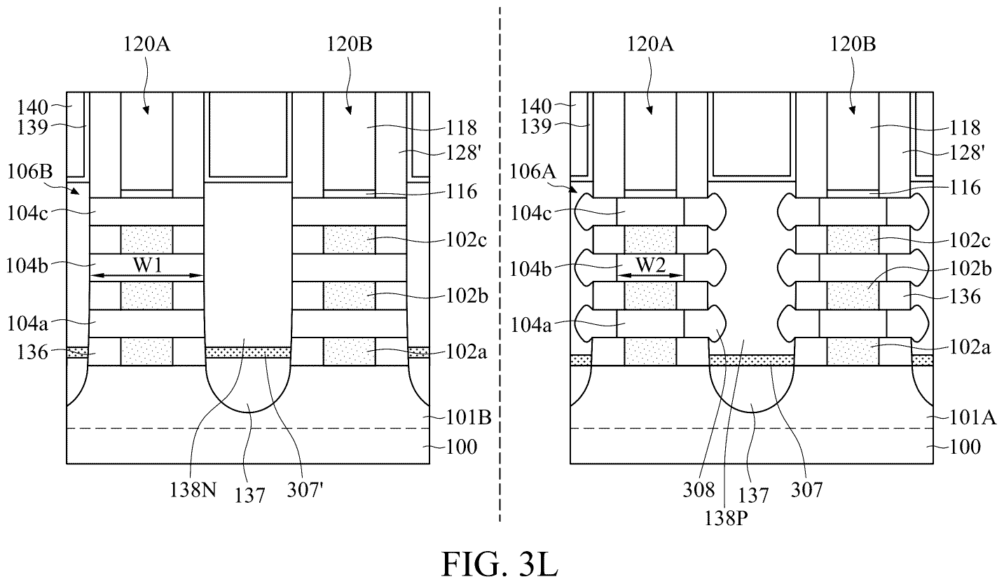

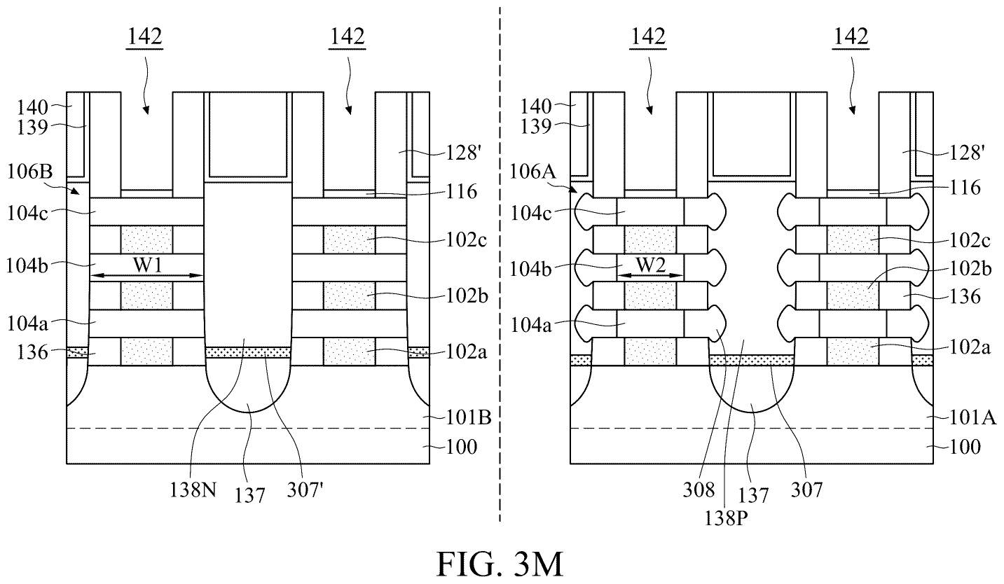

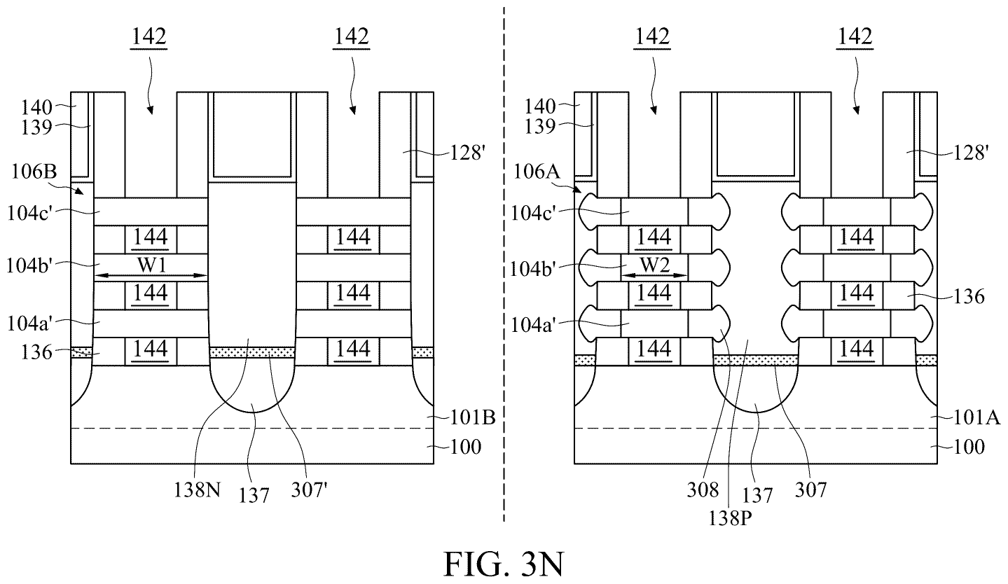

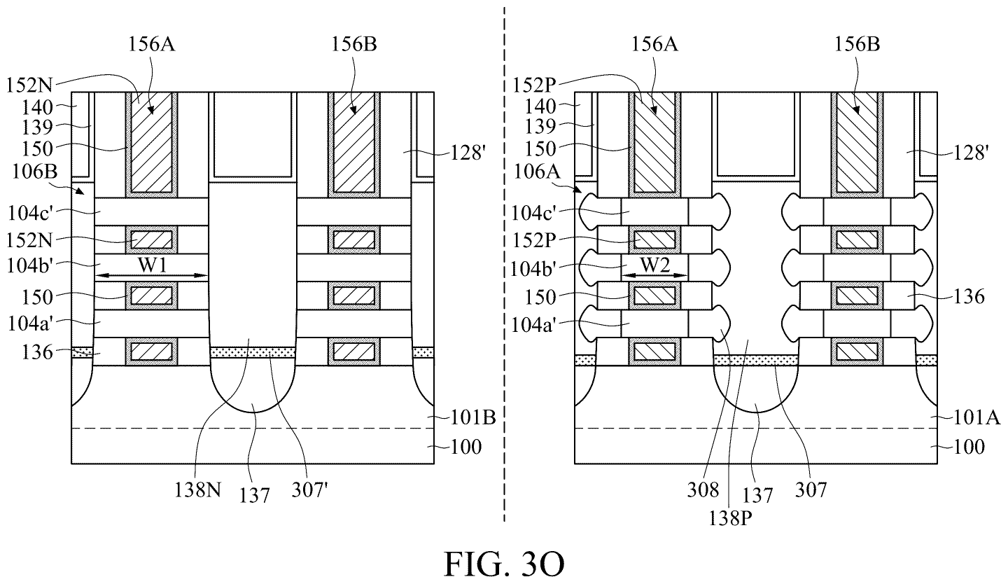

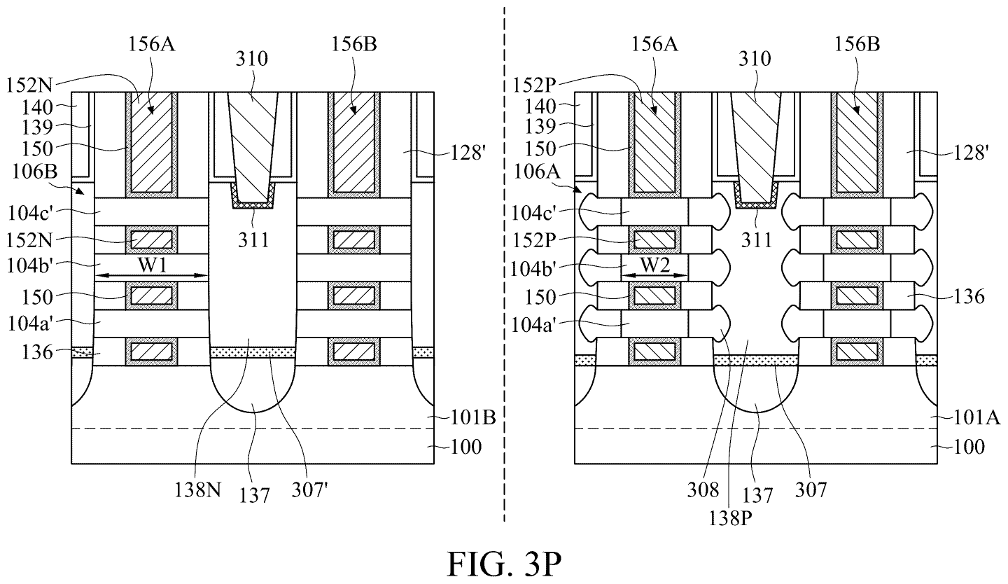

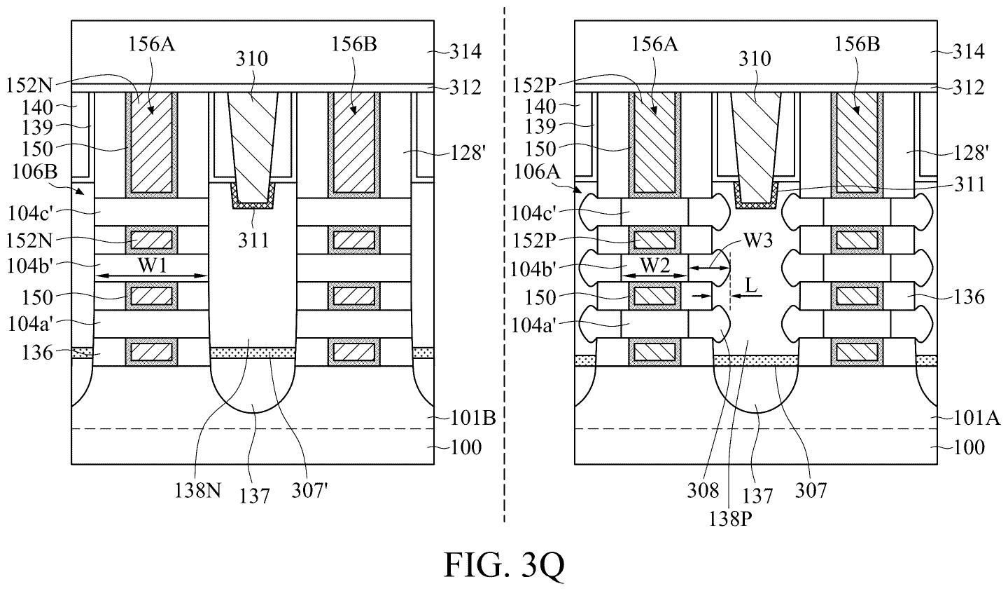

Afterwards, dummy gate stacks 120A and 120B are formed to extend across the fin structures 106A and 106B, as shown in FIG. 1B in accordance with some embodiments. In some embodiments, FIG. 2D is a cross-sectional view of the structure taken along the line 2D-2D in FIG. 1B. FIGS. 3A-3Q are cross-sectional views of various stages of a process for forming portions of a semiconductor device structure, in accordance with some embodiments. In some embodiments, FIG. 3A is a cross-sectional view of two portions of the structure taken along the lines 3A-1 to 3A-1 and 3A-2 to 3A-2 in FIG. 1B.

As shown in FIGS. 1B, 2D, and 3A, the dummy gate stacks 120A and 120B partially cover and extend across the fin structures 106A and 106B, in accordance with some embodiments. In some embodiments, the dummy gate stacks 120A and 120B partially cover the fin structures 106A and 106B. As shown in FIG. 2D, the dummy gate stack 120B extends across and is wrapped around the fin structures 106A and 106B. As shown in FIG. 1B, other portions of the fin structures 106A and 106B are exposed without being covered by the dummy gate stack 120A or 120B.

As shown in FIGS. 2D and 3A, each of the dummy gate stacks 120A and 120B includes a dummy gate dielectric layer 116 and a dummy gate electrode 118. The dummy gate dielectric layer 116 may be made of or include silicon oxide or another suitable material. The dummy gate electrodes 118 may be made of or include polysilicon or another suitable material.

In some embodiments, a dummy gate dielectric material layer and a dummy gate electrode layer are sequentially deposited over the isolation structure 115 and the fin structures 106A and 106B. The dummy gate dielectric material layer may be deposited using an ALD process, a CVD process, one or more other applicable processes, or a combination thereof. The dummy gate electrode layer may be deposited using a CVD process. Afterwards, the dummy gate dielectric material layer and the dummy gate electrode layer are patterned to form the dummy gate stacks 120A and 120B.

In some embodiments, hard mask elements are used to assist in the patterning process for forming the dummy gate stacks 120A and 120B. With the hard mask elements as an etching mask, one or more etching processes are used to partially remove the dummy gate dielectric material layer and the dummy gate electrode layer. As a result, remaining portions of the dummy gate dielectric material layer and the dummy gate electrode layer form the dummy gate stacks 120A and 120B.

As shown in FIG. 3A, gate spacers 128′ are then formed over the sidewalls of the dummy gate stacks 120A and 120B, in accordance with some embodiments. In some embodiments, one or more spacer layers are deposited over the dummy gate stacks 120A and 120B and the fin structures 106A and 106B. The spacer layers extend along the tops and sidewalls of the dummy gate stacks 120A and 120B.

The spacer layers may be made of or include silicon nitride, silicon oxynitride, carbon-containing silicon nitride, carbon-containing silicon oxynitride, silicon oxide, carbon-containing silicon oxide, aluminum oxide, hafnium oxide, one or more other suitable materials, or a combination thereof. In some embodiments, one or more of the spacer layers is/are made of a high-k material. The spacer layers may be deposited using a CVD process, an ALD process, a physical vapor deposition (PVD) process, another applicable process, or a combination thereof.

Afterwards, the spacer layers are partially removed, in accordance with some embodiments. One or more anisotropic etching processes may be used to partially remove the spacer layers. As a result, remaining portions of the spacer layers form the gate spacers 128′. The gate spacers 128′ extend along the sidewalls of the dummy gate stacks 120A and 120B, as shown in FIG. 3A.

As shown in FIG. 3B, the fin structures 106A and 106B are partially removed, in accordance with some embodiments. As a result, multiple recesses 130 are formed. The recesses 130 expose the side edges of the semiconductor layers 102a-102c and 104a-104c. The recesses 130 may be used to contain epitaxial structures (such as source/drain structures) that will be formed later. Source/drain structures (or region(s)) may refer to a source or a drain, individually or collectively dependent upon the context. In some embodiments, the recesses 130 formed in the fin structure 106A are used for containing p-type doped epitaxial structures that will be formed later. In some embodiments, the recesses 130 formed in the fin structure 106B are used for containing n-type doped epitaxial structures that will be formed later.

One or more etching processes may be used to form the recesses 130. In some embodiments, a dry etching process is used to form the recesses 130. Alternatively, a wet etching process may be used to form the recesses 130. The recesses 130 penetrate into the fin structures 106A and 106B. In some embodiments, the recesses 130 further extend into the semiconductor fins 101A and 101B, as shown in FIG. 3B.

In some embodiments, the recesses 130 have substantially vertical sidewalls. In these cases, due to the profile of the recesses 130, an upper semiconductor layer (such as the semiconductor layer 104c) is substantially as wide as a lower semiconductor layer (such as the semiconductor layer 104b).

However, embodiments of the disclosure have many variations. In some other embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104c) is shorter than a lower semiconductor layer (such as the semiconductor layer 104b).

Afterwards, as shown in FIG. 3C, the semiconductor layers 102a-102c are laterally etched, in accordance with some embodiments. As a result, edges of the semiconductor layers 102a-102c retreat from edges of the semiconductor layers 104a-104c. The side edges of the semiconductor layers 102a-102c are pulled back. As shown in FIG. 3C, recesses 132 are formed due to the lateral etching of the semiconductor layers 102a-102c. The recesses 132 may be used to contain inner spacers that will be formed later. The semiconductor layers 102a-102c may be laterally etched using a wet etching process, a dry etching process, or a combination thereof. In some other embodiments, the semiconductor layers 102a-102c are partially oxidized before being laterally etched.

As shown in FIG. 3D, inner spacers 136 are formed in the recesses 132, in accordance with some embodiments. The inner spacers 136 cover the side edges of the semiconductor layers 102a-102c. The inner spacers 136 may be used to prevent subsequently formed epitaxial structures (which function as, for example, source/drain structures) from being damaged during a subsequent process for removing the semiconductor layers 102a-102c. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure may be improved.

In some embodiments, an insulating layer is deposited over the structure shown in FIG. 3C, in accordance with some embodiments. The insulating layer covers the dummy gate stacks 120A and 120B and fills the recesses 132. The insulating layer may be made of or include carbon-containing silicon nitride (SiCN), carbon-containing silicon oxynitride (SiOCN), carbon-containing silicon oxide (SiOC), silicon oxide, silicon nitride, aluminum oxide, hafnium oxide, one or more other suitable materials, or a combination thereof. In some embodiments, the insulating layer is a single layer. In some other embodiments, the insulating layer includes multiple sub-layers. Some of the sub-layers may be made of different materials and/or contain different compositions. The insulating layer may be deposited using a CVD process, an ALD process, one or more other applicable processes, or a combination thereof.

Afterwards, one or more etching processes are used to partially remove the insulating layer, in accordance with some embodiments. The portions of the insulating layer outside of the recesses 132 may be removed. The remaining portions of the insulating layer form the inner spacers 136, as shown in FIG. 3D. The etching process may include a dry etching process, a wet etching process, or a combination thereof. In some embodiments, the compositions of the inner spacers 136 and the gate spacers 128′ are different, so as to provide etching selectivity between the inner spacers 136 and the gate spacers 128′.

In some embodiments, after the etching process for forming the inner spacers 136, portions of the semiconductor fins 101A and 101B originally covered by the insulating layer are exposed by the recesses 130, as shown in FIG. 3D. The side edges of the semiconductor layers 104a-104c are exposed by the recesses 130, as shown in FIG. 3D.

As shown in FIG. 3E, semiconductor isolation structures 137 are formed over the bottoms of the recesses 130, in accordance with some embodiments. In some embodiments, the semiconductor isolation structures 137 are epitaxial structures that are undoped. In some embodiments, the semiconductor isolation structures 137 are substantially free of n-type dopants or p-type dopants.

The semiconductor isolation structures 137 may be made of or include silicon, silicon germanium, another suitable material, or a combination thereof. The semiconductor isolation structures 137 may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, another applicable process, or a combination thereof. In some embodiments, the formation of the semiconductor isolation structures 137 involve one or more etching processes that are used to fine-tune the profiles of the semiconductor isolation structures 137. In some embodiments, the semiconductor isolation structures 137 on the semiconductor fins 101A and 101B are formed simultaneously.

In some embodiments, the semiconductor isolation structures 137 are formed to have substantially planar top surfaces, as shown in FIG. 3E. In some embodiments, the top surfaces of the semiconductor isolation structures 137 are positioned at a height level that is lower than the bottom surface of the semiconductor layer 104a. In some embodiments, the top surfaces of the semiconductor isolation structures 137 and the top surfaces of the semiconductor fins 101A and 101B are substantially level. In some embodiments, the top surfaces of the semiconductor isolation structures 137 are higher than the top surfaces of the semiconductor fins 101A and 101B. In some embodiments, the semiconductor isolation structures 137 are in direct contact with some of the inner spacers 136, as shown in FIG. 3E.

Many variations and/or modifications can be made to embodiments of the disclosure. In some other embodiments, the semiconductor isolation structures 137 are not formed.

As shown in FIG. 3F, a mask element 302 is formed to cover the fin structure 106A, the semiconductor isolation structures 137 on the semiconductor fin 101A, and portions of the dummy gate stacks 120A and 120B near the fin structure 106A, in accordance with some embodiments. The fin structure 106B, the semiconductor isolation structures 137 on the semiconductor fin 101B, and portions of the dummy gate stacks 120A and 120B near the fin structure 106B are exposed without being covered by the mask element 302.

In some embodiments, a mask element layer is formed over the structure shown in FIG. 3E. Afterwards, a patterned photoresist layer is formed over the mask element layer. With the patterned photoresist layer as an etching mask, an etching process is used to partially remove the mask element. As a result, the remaining portion of the mask element under the patterned photoresist layer forms the mask element 302. Then, the patterned photoresist layer is removed.

Afterwards, epitaxial structures 138N are formed on the side edges of semiconductor layers 104a-104c and the semiconductor fin 101B that are not covered by the mask element 302, in accordance with some embodiments. In some embodiments, the epitaxial structures 138N fill the recesses 130 that are not covered by the mask element 302, as shown in FIG. 3F. In some embodiments, the epitaxial structures 138N overfill the recesses 130 to ensure fully contact between the epitaxial structures 138N and the side edges of the semiconductor layer 104c nearby. In some embodiments, the top surfaces of the epitaxial structures 138N are higher than the top surface of the dummy gate dielectric layer 116. In some other embodiments, the epitaxial structures 138N partially fill the recesses 130.

In some embodiments, the epitaxial structures 138N connect to some of the semiconductor layers 104a-104c. Some of the semiconductor layers 104a-104c are sandwiched between the epitaxial structures 138N. In some embodiments, the epitaxial structures 138N are n-type doped epitaxial structures. The epitaxial structures 138N may include epitaxially grown silicon, epitaxially grown silicon germanium (SiGe), or another suitable epitaxially grown semiconductor material.

In some embodiments, the epitaxial structures 138N are formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof. In some embodiments, the formation of the epitaxial structures 138N involves one or more etching processes that are used to fine-tune the shapes of the epitaxial structures 138N.

In some embodiments, the epitaxial structures 138N are doped with one or more suitable n-type dopants. For example, the epitaxial structures 138N are Si source/drain features that are doped with phosphor (P), antimony (Sb), arsenic (As) or another suitable dopant. In some embodiments, each of the epitaxial structures 138N has a first region and a second region over the first region. The second region may have a greater dopant concentration than that of the first region.

In some embodiments, the epitaxial structures 138N are doped in-situ during their epitaxial growth. The initial reaction gas mixture for forming the epitaxial structures 138N contains dopants. In some other embodiments, the epitaxial structures 138N are not doped during the growth of the epitaxial structures 138N. Instead, after the formation of the epitaxial structures 138N, the epitaxial structures 138N are doped in a subsequent process. In some embodiments, the doping is achieved by using an ion implantation process, a plasma immersion ion implantation process, a gas and/or solid source diffusion process, one or more other applicable processes, or a combination thereof. In some embodiments, the epitaxial structures 138N are further exposed to one or more annealing processes to activate the dopants. For example, a rapid thermal annealing process is used.

In some embodiments, before the formation of the epitaxial structures 138N, bottom isolation structures 307′ are formed over the semiconductor isolation structures 137 that are exposed. The bottom isolation structures 307′ may be made of one or more dielectric materials. The bottom isolation structures 307′ may be made of or include silicon nitride, silicon oxide, silicon oxynitride, carbon-containing silicon nitride, carbon-containing silicon oxynitride, carbon-containing silicon oxide, hafnium oxide, aluminum oxide, another suitable material, or a combination thereof.

A dielectric layer may be deposited over the sidewalls and bottoms of the recesses 130. The portions of the dielectric layer extending along the sidewalls of the recesses 130 may be thinner than the portions of the dielectric layer over the bottoms of the recesses 130. Afterwards, one or more etching processes may be used to remove the portions of the dielectric layer extending along the sidewalls of the recesses 130. As a result, the remaining portions of the dielectric layer form the bottom isolation structures 307′.

As shown in FIG. 3G, the mask element 302 is removed, and a mask element 304 is formed to cover the epitaxial structures 138N, in accordance with some embodiments. A pattern photoresist layer 305 is formed to assist in the formation of the mask element 304. After the removal of the mask element 302, the fin structure 106A and the semiconductor isolation structures 137 on the semiconductor fin 101A are exposed. Afterwards, in some embodiments, bottom isolation structures 307 are formed, as shown in FIG. 3G. The material and formation method of the bottom isolation structures 307 may be the same as or similar to those of the bottom isolation structures 307′.

As shown in FIG. 3H, the patterned photoresist layer 305 is removed, in accordance with some embodiments. The epitaxial structures 138N and the portions of the dummy gate stacks 120A and 120B and the gate spacers 128′ nearby remain covered by the mask element 304.

Afterwards, the semiconductor layers 104a-104c of the fin structure 106A are recessed, as shown in FIG. 3H in accordance with some embodiments. In some embodiments, the semiconductor layers 104a-104c are laterally etched from the exposed side edges of the semiconductor layers 104a-104c. As a result, the side edges of the semiconductor layers 104a-104c retreat from edges of the inner spacers 136. The side edges of the semiconductor layers 104a-104c are pulled back.

In some embodiments, recesses 306 are formed due to the lateral etching of the semiconductor layers 104a-104c, as shown in FIG. 3H. The semiconductor layers 104a-104c may be laterally etched using a wet etching process, a dry etching process, or a combination thereof. In some other embodiments, the semiconductor layers 104a-104c are partially oxidized before being laterally etched.

As shown in FIG. 3H, the semiconductor layers 104a-104c of the fin structure 106B have a length W1, and the semiconductor layers 104a-104c of the fin structure 106A have a length W2. The length W1 is longer than the length W2. The semiconductor layers 104a-104c of the fin structure 106B are prevented from being laterally etched since they are covered by the epitaxial structures 138N and the mask element 304. Therefore, each of the semiconductor layers 104a-104c of the fin structure 106B is longer than each of the semiconductor layers 104a-104c of the fin structure 106A. The semiconductor layers 104a-104c with the length W2 may be formed into channel structures of a PMOS transistor in subsequent processes. The channel structures that are shorter may have lower channel resistance, thereby improving performance.

As shown in FIG. 3I, multiple epitaxial structures 308 are formed from the side edges of the semiconductor layers 104a-104c, in accordance with some embodiments. Each of the epitaxial structures 308 is formed on a respective edge of the semiconductor layers 104a-104c. In some embodiments, the epitaxial structures 308 protrude past the outer edges of the inner spacers 136. The epitaxial structures 308 partially occupy the recesses 130. Portions of the recesses 130 remain unoccupied, as shown in FIG. 3I. In some embodiments, the inner spacers 136 extend across the interfaces between the epitaxial structures 308 and the semiconductor layers 104a-104c.

In some embodiments, the epitaxial structures 308 connect to the semiconductor layers 104a-104c. In some embodiments, the epitaxial structures 308 are p-type doped epitaxial structures. In some embodiments, the epitaxial structures 308 contain silicon. The epitaxial structures 308 may include epitaxially grown silicon doped with one or more kinds of p-type dopants. In some embodiments, the epitaxial structures 308 are doped with boron. The dopant concentration may be higher than about 10²⁰/cm³. For example, the boron dopant concentration may be within a range from about 10²⁰/cm³ to about 10²²/cm³. In some embodiments, at the stage illustrated in FIG. 3I, the epitaxial structures 308 are substantially free of germanium. In some embodiments, the epitaxial structures 308 are boron-doped silicon epitaxial structures.

In some embodiments, the epitaxial structures 308 are formed or grown on the exposed surfaces of the semiconductor layers 104a-104c using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the epitaxial structures 308 are selectively grown on the exposed semiconductor surfaces of the semiconductor layers 104a-104c without being substantially grown on the surface of the bottom isolation structures 307 and the surfaces of the inner spacers 136. In some embodiments, due to the blocking of the bottom isolation structures 307, there is no semiconductor material directly grown on the semiconductor fin 101A and the semiconductor isolation structures 137 during the growth of the epitaxial structures 308.

As shown in FIG. 3J, epitaxial structures 138P are formed over the semiconductor fin 101A and the epitaxial structures 308, in accordance with some embodiments. In some embodiments, the epitaxial structures 138P are in contact with the epitaxial structures 308. In some embodiments, the epitaxial structures 308 are wrapped around the terminal portions of the epitaxial structures 138P, as shown in FIG. 3J. In some embodiments, each of the epitaxial structures 308 has an inner portion and an extrusion portion that extends into the epitaxial structure 138P nearby. The inner portion is between the extrusion portion and the semiconductor layer 104a, 104b or 104c. The extrusion portion of the epitaxial structures 308 may include another shape profile other than those shown in FIG. 3J. The shape of the extrusion portion of the epitaxial structures 308 may also include square, triangle, trapezoid, oval, or another suitable shape.

In some embodiments, the epitaxial structures 138P fill the recesses 130 that are not covered by the mask element 304. In some other embodiments, the epitaxial structures 138P overfill the recesses 130 to ensure fully contact between the epitaxial structures 138P and the epitaxial structures 308 nearby. In some embodiments, the top surfaces of the epitaxial structures 138P are higher than the top surface of the dummy gate dielectric layer 116. In some other embodiments, the epitaxial structures 138P partially fill the recesses 130.

In some embodiments, the epitaxial structures 138P connect to some of the semiconductor layers 104a-104c through the epitaxial structures 308. Some of the semiconductor layers 104a-104c are sandwiched between the epitaxial structures 138P. In some embodiments, the epitaxial structures 138P are p-type epitaxial structures. In some embodiments, the epitaxial structures 138P contain germanium. The epitaxial structures 138P may include epitaxially grown silicon germanium or another suitable epitaxially grown semiconductor material. The epitaxial structures 138P may have an atomic concentration of germanium that is within a range from about 20% to about 70%.

In some embodiments, the epitaxial structures 138P are formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof. In some embodiments, the formation of the epitaxial structures 138P involves one or more etching processes that are used to fine-tune the shapes of the epitaxial structures 138P.

In some embodiments, the epitaxial structures 138P are doped with one or more suitable p-type dopants. For example, the epitaxial structures 138P are SiGe source/drain features that are doped with boron (B), gallium (Ga), indium (In), or another suitable dopant. In some embodiments, each of the epitaxial structures 138P has a first region and a second region over the first region. The second region may have a greater dopant concentration than that of the first region.

In some embodiments, the epitaxial structures 138P are doped in-situ during their epitaxial growth. The initial reaction gas mixture for forming the epitaxial structures 138P contains dopants. In some other embodiments, the epitaxial structures 138P are not doped during the growth of the epitaxial structures 138P. Instead, after the formation of the epitaxial structures 138P, the epitaxial structures 138P are doped in a subsequent process. In some embodiments, the doping is achieved by using an ion implantation process, a plasma immersion ion implantation process, a gas and/or solid source diffusion process, one or more other applicable processes, or a combination thereof. In some embodiments, the epitaxial structures 138P are further exposed to one or more annealing processes to activate the dopants. For example, a rapid thermal annealing process is used.

In some embodiments, some germanium atoms from the epitaxial structures 138P may diffuse into the epitaxial structures 308 that are nearby. In these cases, the epitaxial structures 308 may contain germanium. The epitaxial structures 308 may have an atomic concentration of germanium that is within a range from about 0% to about 5%. In some embodiments, the atomic concentration of germanium of each of the epitaxial structures 308 gradually decreases along a direction from the epitaxial structure 138P nearby towards one of the semiconductor layers 104a-104c.

In some embodiments, the epitaxial structures 138P have a higher atomic concentration of germanium than that of the epitaxial structures 308. In some embodiments, the epitaxial structures 308 have a higher atomic concentration of silicon than that of the epitaxial structures 138P. The p-type dopants, such as boron, have lower diffusivity in the silicon germanium-based epitaxial structures 138P compared to the silicon-based epitaxial structures 308. The diffusion of the p-type dopant, such as boron, is enhanced by the epitaxial structures 308, thereby reducing resistance and improving performance.

In some embodiments illustrated in FIGS. 3F-3J, the epitaxial structures 138N are formed before the epitaxial structures 138P and 308. However, embodiments of the disclosure are not limited thereto. Many variations and/or modifications can be made to embodiments of the disclosure. In some other embodiments, the epitaxial structures 308 and 138P are formed before the epitaxial structures 138N.

Afterwards, the mask element 304 is removed, as shown in FIG. 3K in accordance with some embodiments. The epitaxial structures 138N and the portions of the dummy gate stacks 120A and 120B that are originally covered by the mask element 304 are thus exposed.

As shown in FIG. 3L, a contact etch stop layer 139 and a dielectric layer 140 are formed over the epitaxial structures 138N and 138P to laterally surround the dummy gate stacks 120A and 120B, in accordance with some embodiments. The contact etch stop layer 139 may be made of or include silicon nitride, silicon oxynitride, silicon carbide, aluminum oxide, another suitable material, or a combination thereof. The dielectric layer 140 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof.

In some embodiments, an etch stop material layer and a dielectric material layer are sequentially deposited. The etch stop material layer may be deposited using a CVD process, an ALD process, a PVD process, one or more other applicable processes, or a combination thereof. The dielectric material layer may be deposited using an FCVD process, a CVD process, an ALD process, another applicable process, or a combination thereof.

Afterwards, a planarization process is used to partially remove the etch stop material layer and the dielectric material layer. As a result, the remaining portions of the etch stop material layer and the dielectric material layer respectively form the contact etch stop layer 139 and the dielectric layer 140, as shown in FIG. 3L. The planarization process may include a CMP process, a grinding process, an etching process, a dry polishing process, one or more other applicable processes, or a combination thereof.

In some embodiments, the mask elements used for defining the dummy gate stacks 120A and 120B are removed during the planarization process. In some embodiments, after the planarization process, the top surfaces of the contact etch stop layer 139, the dielectric layer 140, and the dummy gate electrodes 118 are substantially level.

Afterwards, as shown in FIG. 3M, the dummy gate electrodes 118 are removed to form trenches 142 using one or more etching processes, in accordance with some embodiments. The trenches 142 are surrounded by the dielectric layer 140. The trenches 142 expose the dummy gate dielectric layer 116.

As shown in FIG. 3N, the dummy gate dielectric layer 116 and the semiconductor layers 102a-102c (which function as sacrificial layers) are removed, in accordance with some embodiments. In some embodiments, one or more etching processes are used to remove the dummy gate dielectric layer 116 and the semiconductor layers 102a-102c. As a result, recesses 144 are formed, as shown in FIG. 3N.

Due to high etching selectivity, the semiconductor layers 104a-104c are slightly (or substantially not) etched. The remaining portions of the semiconductor layers 104a-104c form multiple semiconductor nanostructures 104a′-104c′. The semiconductor nanostructures 104a′-104c′ are constructed by or made up of the remaining portions of the semiconductor layers 104a-104c. The semiconductor nanostructures 104a′-104c′ suspended over the semiconductor fins 101A and 101B may function as the channel structures of transistors.

In some other embodiments, the etchant used for removing the semiconductor layers 102a-102c also slightly removes the semiconductor layers 104a-104c that form the semiconductor nanostructures 104a′-104c′. As a result, the obtained semiconductor nanostructures 104a′-104c′ become thinner after the removal of the semiconductor layers 102a-102c. In some embodiments, each of the semiconductor nanostructures 104a′-104c′ is thinner than the edge portions since the edge portions are surrounded by other elements and thus are prevented from being reached and etched by the etchant.

After the removal of the semiconductor layers 102a-102c (which function as sacrificial layers), the recesses 144 are formed. The recesses 144 connect to the trench 142 and surround each of the semiconductor nanostructures 104a′-104c′. As shown in FIG. 3N, even if the recesses 144 between the semiconductor nanostructures 104a′-104c′ are formed, the semiconductor nanostructures 104a′-104c′ remain held by the neighboring elements including the epitaxial structures 138N, 138P, 308 and the inner spacers 136. Therefore, after the removal of the dummy gate stacks 120A and 120B and the semiconductor layers 102a-102c (which function as sacrificial layers), the released semiconductor nanostructures 104a′-104c′ are prevented from falling.

During the removal of the semiconductor layers 102a-102c (which function as sacrificial layers), the inner spacers 136 protect the epitaxial structures 138N and 138P from being etched or damaged. In some embodiments, the silicon-based epitaxial structures 308 may also help to protect the silicon germanium-based epitaxial structures 138P from being etched or damaged during the removal of the semiconductor layers 102a-102c that are also silicon germanium-based. The quality and reliability of the semiconductor device structure are improved.

As shown in FIG. 3O, metal gate stacks 156A and 156B are formed to fill the trenches 142, in accordance with some embodiments. The metal gate stacks 156A and 156B further extend into the recesses 144 to wrap around each of the semiconductor nanostructures 104a′-104c′.

Each of the metal gate stacks 156A and 156B includes multiple metal gate stack layers. Each of the metal gate stacks 156A and 156B may include a gate dielectric layer 150 and metal gate electrodes 152P and 152N. Each of the metal gate electrodes 152P and 152N may include a work function layer. Each of the metal gate electrodes 152P and 152N may further include a conductive filling. In some embodiments, the formation of the metal gate stacks 156A and 156B involves the deposition of multiple metal gate stack layers over the dielectric layer 140 to fill the trenches 142 and the recesses 144. The metal gate stack layers extend into the recesses 144 to wrap around each of the semiconductor nanostructures 104a′-104c′.

In some embodiments, the gate dielectric layer 150 is made of or includes a dielectric material with high dielectric constant (high-K). The gate dielectric layer 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layer 150 may be deposited using an ALD process, a CVD process, one or more other applicable processes, or a combination thereof.

In some embodiments, before the formation of the gate dielectric layer 150, an interfacial layers are formed on the surfaces of the semiconductor nanostructures 104a′-104c′. The interfacial layers are very thin and are made of, for example, silicon oxide or germanium oxide. In some embodiments, the interfacial layers are formed by applying an oxidizing agent on the surfaces of the semiconductor nanostructures 104a′-104c′. For example, a hydrogen peroxide-containing liquid may be applied or provided on the surfaces of the semiconductor nanostructures 104a′-104c′ so as to form the interfacial layers.

The work function layer of the metal gate electrodes 152P and 152N may be used to provide the desired work function for transistors to enhance device performance including improved threshold voltage. The metal gate electrodes 152P and 152N may have different work function layers. In some embodiments, the work function layer surrounding the semiconductor nanostructures 104a′-104c′ of the fin structure 106A is used for forming a PMOS device. In these cases, the work function layer of the metal gate electrode 152P is a p-type work function layer. The p-type work function layer is capable of providing a work function value suitable for the device, such as equal to or greater than about 4.8 eV.

The p-type work function layer may include metal, metal carbide, metal nitride, other suitable materials, or a combination thereof. For example, the p-type metal includes tantalum nitride, tungsten nitride, titanium, titanium nitride, one or more other suitable materials, or a combination thereof.

In some embodiments, the work function layer surrounding the semiconductor nanostructures 104a′-104c′ of the fin structure 106B is used for forming an NMOS device. The work function layer of the metal gate electrode 152N is an n-type work function layer. The n-type work function layer is capable of providing a work function value suitable for the device, such as equal to or less than about 4.5 eV.

The n-type work function layer may include metal, metal carbide, metal nitride, or a combination thereof. For example, the n-type work function layer includes titanium nitride, tantalum, tantalum nitride, one or more other suitable materials, or a combination thereof. In some embodiments, the n-type work function is an aluminum-containing layer. The aluminum-containing layer may be made of or include TiAlC, TiAlO, TiAlN, one or more other suitable materials, or a combination thereof.

The work function layer may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer may be fine-tuned to adjust the work function level.

The work function layer may be deposited over the gate dielectric layer 150 using an ALD process, a CVD process, a PVD process, an electroplating process, an electroless plating process, one or more other applicable processes, or a combination thereof. In some embodiments, the formation of the work function layer involves one or more patterning processes. As a result, the n-type work function layer and the p-type work function layer are selectively formed over different regions.

In some embodiments, a barrier layer is formed before the work function layer to interface the gate dielectric layer 150 with the subsequently formed work function layer. The barrier layer may also be used to prevent diffusion between the gate dielectric layer 150 and the subsequently formed work function layer. The barrier layer may be made of or include a metal-containing material. The metal-containing material may include titanium nitride, tantalum nitride, one or more other suitable materials, or a combination thereof. The barrier layer may be deposited using an ALD process, a CVD process, a PVD process, an electroplating process, an electroless plating process, one or more other applicable processes, or a combination thereof.

In some embodiments, the conductive fillings of the metal gate electrodes 152N and 152P are made of or include a metal material. The metal material may include tungsten, aluminum, copper, cobalt, one or more other suitable materials, or a combination thereof. A conductive layer used for forming the conductive filling may be deposited over the work function layer using a CVD process, an ALD process, a PVD process, an electroplating process, an electroless plating process, a spin coating process, one or more other applicable processes, or a combination thereof.

In some embodiments, a blocking layer is formed over the work function layer before the formation of the conductive layer used for forming the conductive filling. The blocking layer may be used to prevent the subsequently formed conductive layer from diffusing or penetrating into the work function layer. The blocking layer may be made of or include tantalum nitride, titanium nitride, one or more other suitable materials, or a combination thereof. The blocking layer may be deposited using an ALD process, a PVD process, an electroplating process, an electroless plating process, one or more other applicable processes, or a combination thereof.

Afterwards, a planarization process is performed to remove the portions of the metal gate stack layers outside of the trenches 142, in accordance with some embodiments. As a result, the remaining portions of the metal gate stack layers form the metal gate stacks 156A and 156B, as shown in FIG. 3O.

In some embodiments, the conductive filling does not extend into the recesses 144 since the recesses 144 are small and have been filled with other elements such as the gate dielectric layer 150 and the work function layer. However, embodiments of the disclosure are not limited thereto. In some other embodiments, a portion of the conductive filling extends into the recesses 144.

As shown in FIG. 3P, conductive contacts 310 and metal-semiconductor compound structures 311 are formed to establish electrical connection to the respective epitaxial structures 138P and 138N, in accordance with some embodiments. The conductive contacts 310 may penetrate through the dielectric layer 140 and the etch stop layer 139. The metal-semiconductor compound structures 311 are used to improve electrical connection between the conductive contacts 310 and the epitaxial structures 138P and 138N thereunder. In some embodiments, the conductive contacts 310 extend into the epitaxial structures 138P and 138N thereunder.

In some embodiments, the contact etch stop layer 139 and the dielectric layer 140 are partially removed to form contact openings, in accordance with some embodiments. One or more etching processes may be used to form the contact openings that expose the epitaxial structures 138N and 138P.

Afterwards, metal-semiconductor compound structures 311 are formed on the surfaces of the epitaxial structures 138N and 138P that are exposed by the contact openings, in accordance with some embodiments. In some embodiments, before the formation of the metal-semiconductor compound structures 311, the exposed epitaxial structures 138N and 138P are modified to assist in the subsequent formation of the metal-semiconductor compound structures 311. In some embodiments, one or more ion implantation processes are used to reduce the crystallinity of the surface portions of the epitaxial structures 138N and 138P, which allows a subsequently deposited metal material to react with the modified surface portions more easily. The formation of the metal-semiconductor compound structures 311 may thus be facilitated.

In some embodiments, the implantation process is a plasma doping process. Plasma may be introduced into the contact openings to modify the exposed surface portions of the epitaxial structures 138N and 138P. In some embodiments, reaction gas used in the implantation process includes silicon-containing gas, germanium-containing gas, argon-containing gas, helium-containing gas, anther suitable gas, or a combination thereof.

In some embodiments, a metal-containing material is applied (or deposited) on the epitaxial structures 138N and 138P while the epitaxial structures 138N and 138P is heated, in accordance with some embodiments. In some embodiments, the metal-containing material is applied (or deposited) using a CVD process. In some embodiments, the metal-containing material is applied (or deposited) using an atomic layer deposition process. Because the metal-containing material is applied during the heating of the epitaxial structures 138N and 138P, the thermal energy may help to initiate chemical reaction between the surface portions of the epitaxial structures 138N and 138P and the metal-containing material. As a result, the surface portions of the epitaxial structures 138N and 138P react with the metal-containing material, and they are transformed into the metal-semiconductor compound structures 311. The metal-semiconductor compound structures 311 may be made of or include a metal silicide material, a silicon-germanium-metal-containing material, a germanium-metal-containing material, another suitable material, or a combination thereof.

As mentioned above, the metal-containing material is applied (or deposited) on the epitaxial structures 138N and 138P while the epitaxial structures 138N and 138P are heated. In some embodiments, the epitaxial structures 138N and 138P are heated to a temperature that is in a range from about 390 degrees C. to about 440 degrees C. In some embodiments, before the metal-containing material is applied (or deposited) on the epitaxial structures 138N and 138P, the epitaxial structures 138N and 138P are heated to be at a raised temperature. Afterwards, the epitaxial structures 138N and 138P are kept at the raised temperature while the metal-containing material is applied (or deposited). The raised temperature may be in a range from about 390 degrees C. to about 440 degrees C.

In some embodiments, while applying or depositing the metal-containing material for forming the metal-semiconductor compound structures 311, the metal-containing material is also applied (or deposited) on sidewalls and bottom surfaces of the contact openings to form metal layers. The metal layers may be made of or include titanium, cobalt, nickel, tantalum, tungsten, platinum, one or more other suitable materials, or a combination thereof.

Afterwards, a modification process is used to transform the metal layers mentioned above into barrier layers. In some embodiments, the modification process is a plasma-involved process. In some embodiments, the modification process is a process involving nitrogen-containing plasma. In some embodiments, the reaction gases used for generating the nitrogen-containing plasma include NH₃, N₂, Ar, H₂, or a combination thereof. In some embodiments, the metal layers are nitrogenized by the modification process to become the barrier layers extending along the sidewalls of the contact openings. The barrier layers may be made of or include titanium nitride, tantalum nitride, nickel nitride, cobalt nitride, another suitable material, or a combination thereof.

However, embodiments of the disclosure are not limited thereto. Many variations and/or modifications can be made to embodiments of the disclosure. In some other embodiments, the metal-semiconductor compound structures 311 and/or the barrier layers are not formed.

Afterwards, a conductive material layer is deposited to overfill the contact openings, in accordance with some embodiments. The conductive material layer may be made of or include ruthenium, cobalt, tungsten, titanium, molybdenum, tantalum, tungsten, another suitable material, or a combination thereof. The conductive material layer may be deposited using an ALD process, a CVD process, a PVD process, an electroplating process, an electroless plating process, another applicable process, or a combination thereof.

Afterwards, a planarization process is used to remove the conductive material layer outside of the contact openings, in accordance with some embodiments. As a result, the remaining portions of the conductive material layer in the contact openings form the conductive contacts 310. Each of the conductive contacts 310 is electrically connected to the respective epitaxial structure 138N or 138P. The planarization process mentioned above may include a CMP process, a grinding process, an etching process, a dry polishing process, one or more other applicable processes, or a combination thereof.

As shown in FIG. 3Q, an etch stop layer 312 and a dielectric layer 314 are sequentially formed, in accordance with some embodiments. The material and formation method of the etch stop layer 312 may be the same as or similar to those of the contact etch stop layer 139. The material and formation method of the dielectric layer 314 may be the same as or similar to those of the dielectric layer 140. Afterwards, more conductive features, such as conductive vias and conductive lines, may be formed in the dielectric layer 314 and the etch stop layer 139.

Each of the epitaxial structures 308 has a width W3, as shown in FIG. 3Q. The width W3 may be within 1 nm to about 20 nm. In some embodiments, each of the epitaxial structures 308 extends past the edges of the inner spacers 136 nearby. Each of the epitaxial structures 308 has an extrusion portion that extends into the epitaxial structure 138P nearby. In some embodiments, the epitaxial structures 138P are wrapped around the extrusion portions of the epitaxial structures 308, as shown in FIG. 3Q. Each of the extrusion portions of the epitaxial structures 308 has a width L, as shown in FIG. 3Q. The width L may be within a range from about 0.5 nm to about 15 nm.

Embodiments of the disclosure are not limited thereto. Many variations and/or modifications can be made to embodiments of the disclosure. In some other embodiments, some or all of the epitaxial structures 308 do not have any extrusion portion that extends past the edges of the inner spacers 136 nearby and extends into the epitaxial structure 138P nearby.

Many variations and/or modifications can be made to embodiments of the disclosure. In some other embodiments, two or more of the epitaxial structures 308 are formed to merge together.

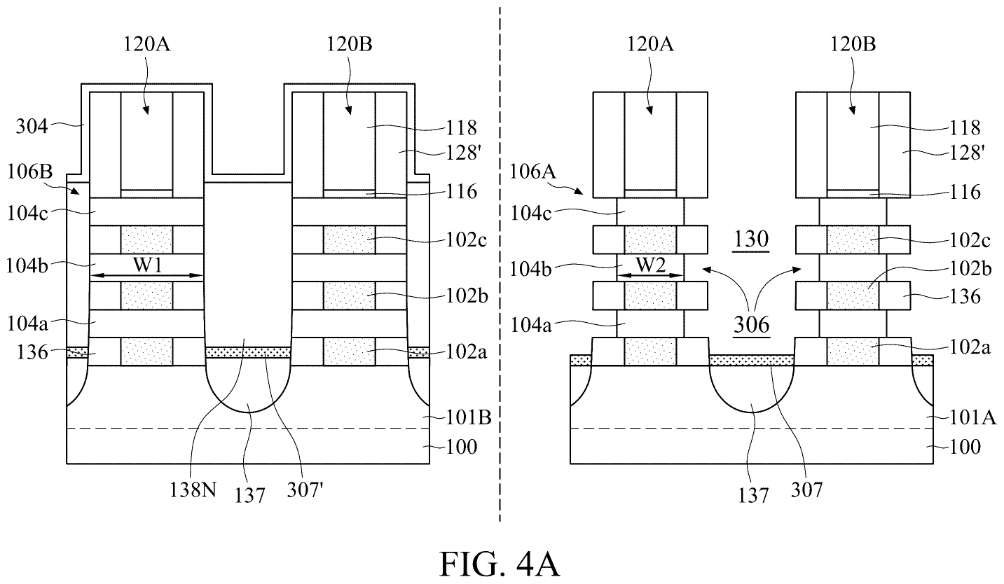

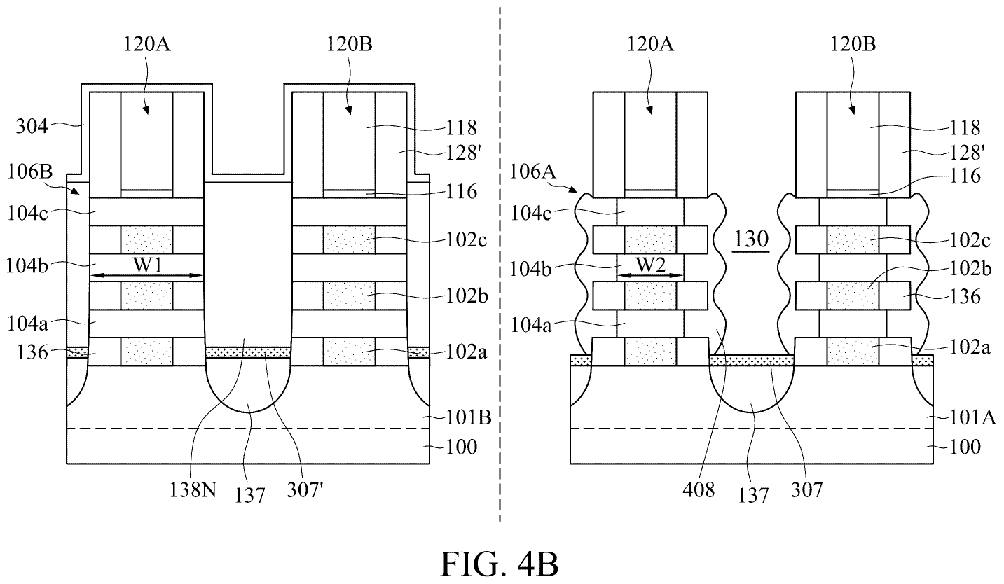

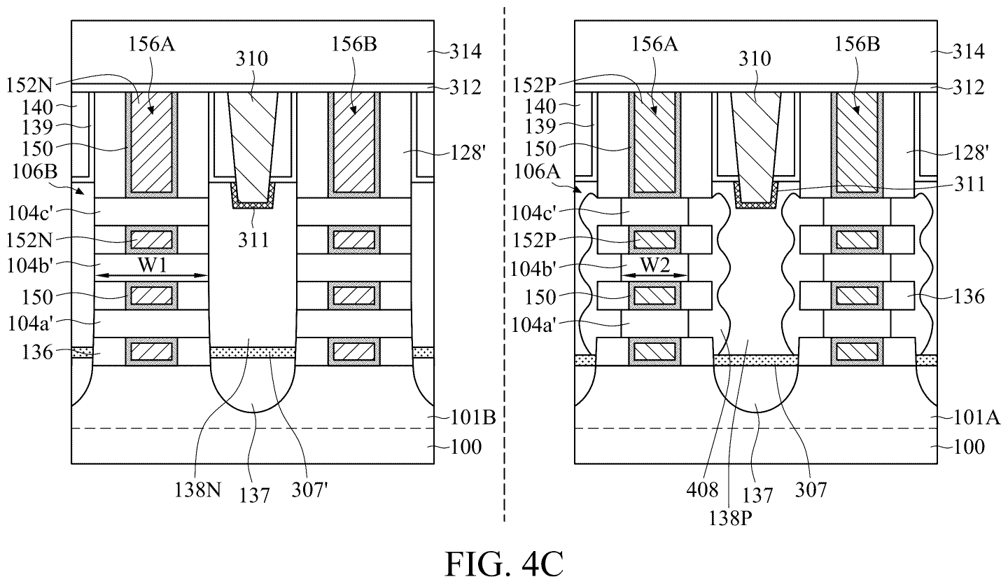

FIGS. 4A-4C are cross-sectional views of various stages of a process for forming portions of a semiconductor device structure, in accordance with some embodiments. As shown in FIG. 4A, a structure that is the same as or similar to the structure shown in FIG. 3H is formed, in accordance with some embodiments.

As shown in FIG. 4B, similar to the embodiments illustrated in FIG. 3I, multiple merged epitaxial structures 408 are formed, in accordance with some embodiments. In some embodiments, multiple epitaxial structures that are similar to the epitaxial structures 308 shown in FIG. 3I are formed. The material and formation method of these epitaxial structures are the same as or similar to those of the epitaxial structures 308 shown in FIG. 3I. In some embodiments, these epitaxial structures are grown for a longer period compared to the epitaxial structures 308. As a result, the adjacent epitaxial structures grow and merge to form the merged epitaxial structures 408, as shown in FIG. 4B.

Afterwards, the process steps that are the same as or similar to those illustrated in FIGS. 3J-3Q are performed. As a result, the structure shown in FIG. 4C is formed, in accordance with some embodiments.

Many variations and/or modification can be made to embodiments of the disclosure. In some other embodiments, the bottom isolation structures 307 and/or 307′ are not formed.

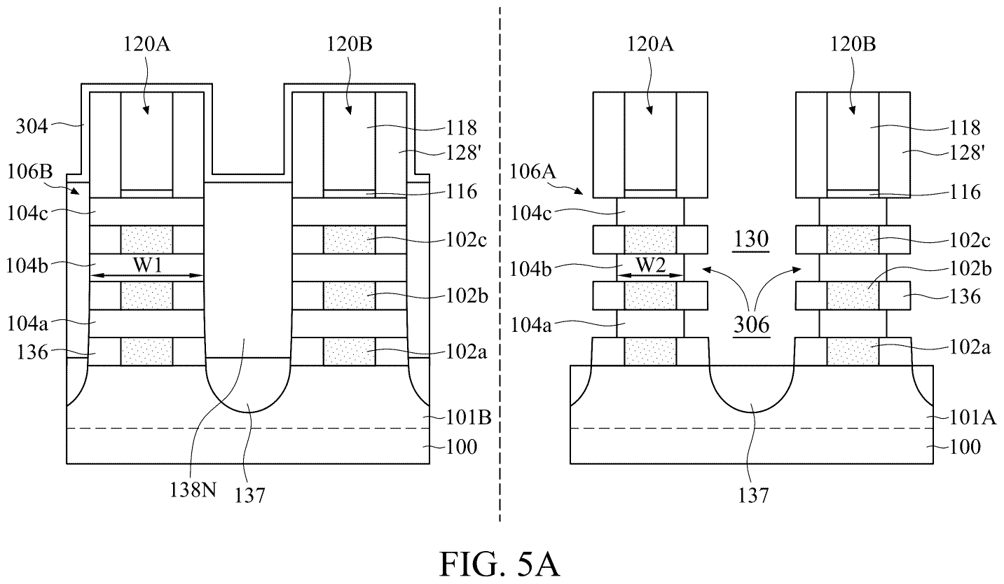

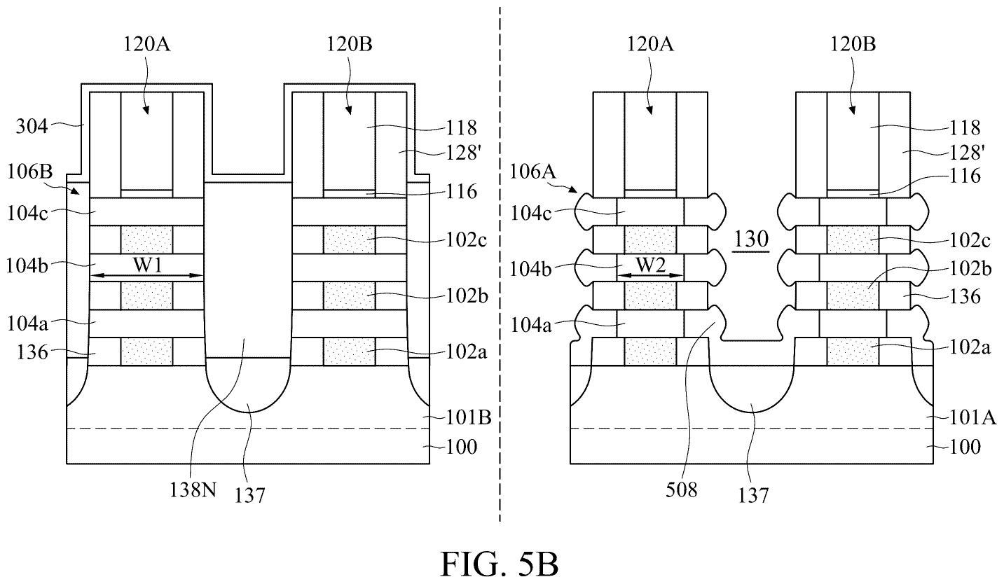

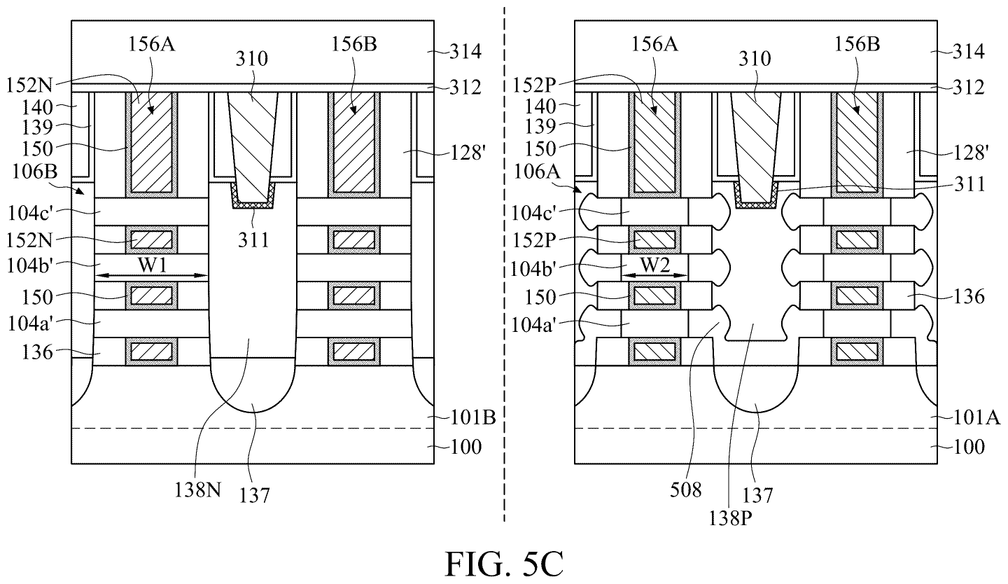

FIGS. 5A-5C are cross-sectional views of various stages of a process for forming portions of a semiconductor device structure, in accordance with some embodiments. As shown in FIG. 5A, a structure that is similar to the structure shown in FIG. 3H is formed, in accordance with some embodiments. As shown in FIG. 5A, no bottom isolation structure is formed between the epitaxial structure 138P (or 138N) and the semiconductor isolation structure 137 thereunder.

As shown in FIG. 5B, similar to the embodiments illustrated in FIG. 3I, multiple epitaxial structures 508 are formed, in accordance with some embodiments. In some embodiments, multiple epitaxial structures 508 that are similar to the epitaxial structures 308 shown in FIG. 3I are formed. The material and formation method of these epitaxial structures are the same as or similar to those of the epitaxial structures 308 shown in FIG. 3I. Since no bottom isolation structure is formed to cover the semiconductor isolation structures 137 and the semiconductor fin 101A, epitaxial structures are also grown on the semiconductor surfaces of the semiconductor isolation structures 137. As a result, the adjacent epitaxial structures at the bottom portion of the recess 130 are formed to merge together, as shown in FIG. 5B.

Afterwards, the process steps that are the same as or similar to those illustrated in FIGS. 3J-3Q are performed. As a result, the structure shown in FIG. 5C is formed, in accordance with some embodiments.

Many variations and/or modifications can be made to embodiments of the disclosure. In some embodiments, for different devices in the same semiconductor structure (such as in the same semiconductor chip), the extrusion portions of the epitaxial structures that extend out of the edges of the inner spacers may have different widths.

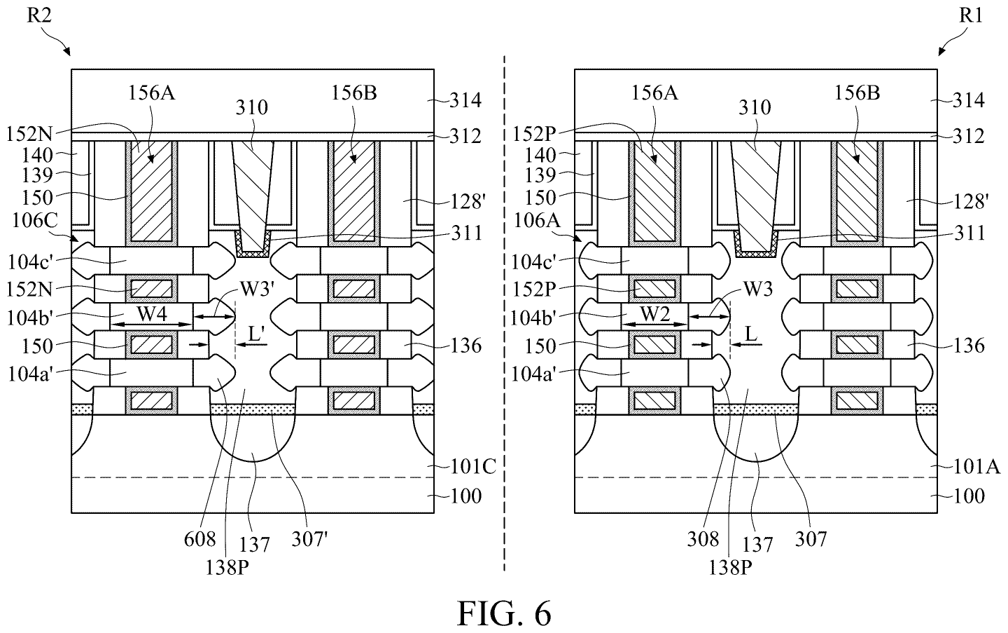

FIG. 6 is a cross-sectional view of portions of a semiconductor device structure, in accordance with some embodiments. As shown in FIG. 6, different devices are formed in regions R1 and R2 of a semiconductor device structure. In some embodiments, a structure that is the same as or similar to the right portion of the structure shown in FIG. 3Q is formed in the region R1.

In some embodiments, the device formed in the region R1 is a portion of a short channel device such as a logic device. In some embodiments, the device formed in the region R2 is a portion of a long channel device such as memory device. For example, a portion of a static random-access memory (SRAM) device is formed in the region R2.

The structure in the region R2 may be formed using similar processes that are illustrated in FIGS. 3A-3Q. In some embodiments, similar to the fin structure 106A, a fin structure 106C is formed. Multiple semiconductor nanostructures 104a′-104c′ are formed over a semiconductor fin 101C. Similar to epitaxial structures 308, epitaxial structures 608 are formed before the formation of the epitaxial structures 138P in the region R2.

As shown in FIG. 6, the semiconductor nanostructures 104a′-104c′ in the region R2 has a length W4, and the semiconductor nanostructures 104a′-104c′ in the region R1 has the length W2. In some embodiments, the length W4 is longer than the length W2. Each of the semiconductor nanostructures 104a′-104c′ in the region R2 is longer than each of the semiconductor nanostructures 104a′-104c′ in the region R1. In some embodiments, separate lateral etching processes are used to pull back the semiconductor layers 104a-104c before the formation of the epitaxial structures 308 and 608. By adjusting the lateral etching of the semiconductor layers 104a-104c in different regions, the lengths of the resulting semiconductor nanostructures 104a′-104c′ can be modified accordingly to meet specific requirements.

As shown in FIG. 6, each of the epitaxial structures 608 has a width W3′. The width W3′ may be within 1 nm to about 20 nm. In some embodiments, the epitaxial structures 308 in the region R1 and the epitaxial structures 608 in the region R2 are simultaneously formed. In some embodiments, each of the epitaxial structures 608 is substantially as wide as each of the epitaxial structures 308. The width W3′ is substantially equal to the width W3.

However, embodiments of the disclosure are not limited thereto. Many variations and/or modifications can be made to embodiments of the disclosure. In some other embodiments, the widths W3 and W3′ are different.

In some embodiments, each of the epitaxial structures 608 extends past the edges of the inner spacers 136 nearby. Each of the epitaxial structures 608 has an extrusion portion that extends into the epitaxial structure 138P nearby. In some embodiments, the epitaxial structures 138P are wrapped around the extrusion portions of the epitaxial structures 608, as shown in FIG. 6. Each of the extrusion portions of the epitaxial structures 608 has a width L′, as shown in FIG. 6. In some embodiments, the extrusion portion of each of the epitaxial structures 608 is wider than the extrusion portion of each of the epitaxial structures 308. The width L′ is wider than the width L.

Embodiments of the disclosure are not limited thereto. Many variations and/or modifications can be made to embodiments of the disclosure. In some other embodiments, some or all of the epitaxial structures 608 do not have any extrusion portion that extends past the edges of the inner spacers 136 nearby and extends into the epitaxial structure 138P nearby.

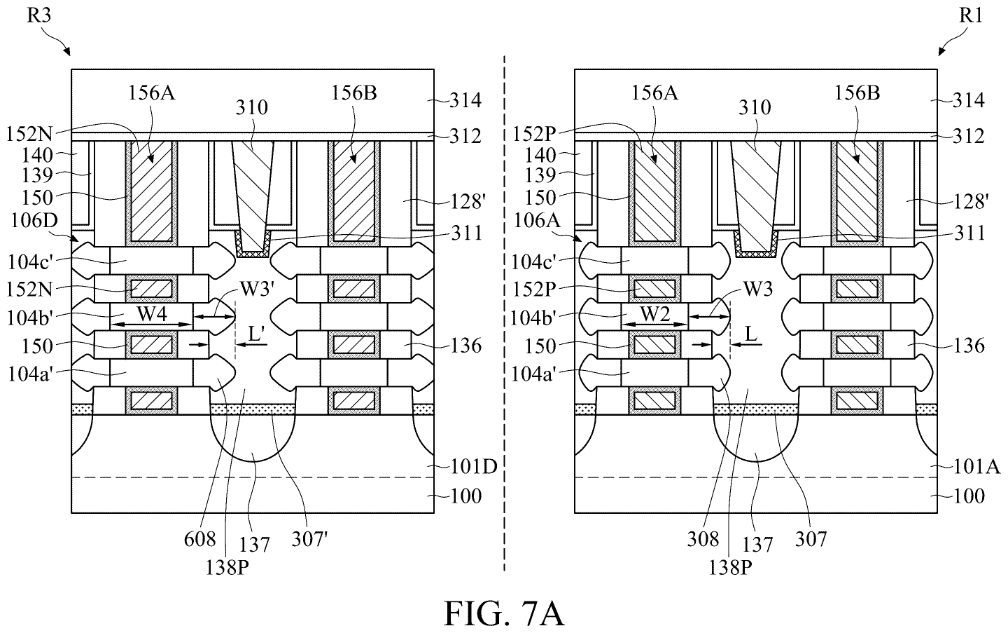

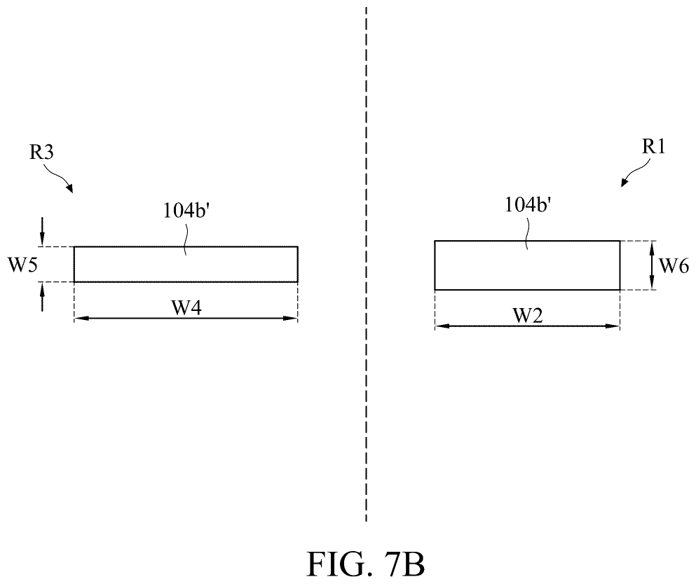

Many variations and/or modifications can be made to embodiments of the disclosure. FIG. 7A is a cross-sectional view of portions of a semiconductor device structure, in accordance with some embodiments. As shown in FIG. 7A, different devices are formed in regions R1 and R3 of a semiconductor device structure. In some embodiments, a structure that is the same as or similar to the right portion of the structure shown in FIG. 3Q is formed in the region R1.

FIG. 7B is a top view of portions of a semiconductor device structure, in accordance with some embodiments. In FIG. 7B, a top view of one of the semiconductor nanostructures 104b′ in the region R3 and a top view of one of the semiconductor nanostructures 104b′ in the region R1 are shown. In some embodiments, the semiconductor nanostructures formed in the regions R1 and the semiconductor nanostructures formed in the regions R3 have different widths and different lengths.

As shown in FIGS. 7A and 7B, in some embodiments, the semiconductor nanostructure 104b′ formed in the region R3 has the length W4 that is longer than the length W2 of the semiconductor nanostructure 104b′ formed in the region R1. As shown in FIG. 7A, the length W2 is measured between the opposite side edges of the semiconductor nanostructure 104b′ that are in contact with the epitaxial structures 308. The length W4 is measured between the opposite side edges of the semiconductor nanostructure 104b′ that are in contact with the epitaxial structures 608. As shown in FIG. 7B, in some embodiments, the semiconductor nanostructure 104b′ formed in the region R3 has a width W4 that is narrower than the width W6 of the semiconductor nanostructure 104b′ formed in the region R1.

The structure in the region R3 may be formed using similar processes that are illustrated in FIGS. 3A-3Q. In some embodiments, similar to the fin structure 106A, a fin structure 106D is formed. Multiple semiconductor nanostructures 104a′-104c′ are formed over a semiconductor fin 101D. Similar to epitaxial structures 308, epitaxial structures 608 are formed before the formation of the epitaxial structures 138P in the region R3.

As shown in FIGS. 7A and 7B, each of the semiconductor nanostructures 104a′-104c′ in the region R3 is longer than each of the semiconductor nanostructures 104a′-104c′ in the region R1. In some embodiments, separate lateral etching processes are used to pull back the semiconductor layers 104a-104c before the formation of the epitaxial structures 308 and 608. By adjusting the lateral etching of the semiconductor layers 104a-104c in different regions, the lengths of the resulting semiconductor nanostructures 104a′-104c′ can be modified accordingly to meet specific requirements.

As shown in FIG. 7A, each of the epitaxial structures 608 has the width W3′. The width W3′ may be within 1 nm to about 20 nm. In some embodiments, the epitaxial structures 308 in the region R1 and the epitaxial structures 608 in the region R3 are simultaneously formed. In some embodiments, each of the epitaxial structures 608 is substantially as wide as each of the epitaxial structures 308. The width W3′ is substantially equal to the width W3.

However, embodiments of the disclosure are not limited thereto. Many variations and/or modifications can be made to embodiments of the disclosure. In some other embodiments, the widths W3 and W3′ are different.

In some embodiments, each of the epitaxial structures 608 extends past the edges of the inner spacers 136 nearby. Each of the epitaxial structures 608 has an extrusion portion that extends into the epitaxial structure 138P nearby. In some embodiments, the epitaxial structures 138P are wrapped around the extrusion portions of the epitaxial structures 608, as shown in FIG. 7A. Each of the extrusion portions of the epitaxial structures 608 has a width L′, as shown in FIG. 7A. In some embodiments, the extrusion portion of each of the epitaxial structures 608 is wider than the extrusion portion of each of the epitaxial structures 308. The width L′ is wider than the width L.

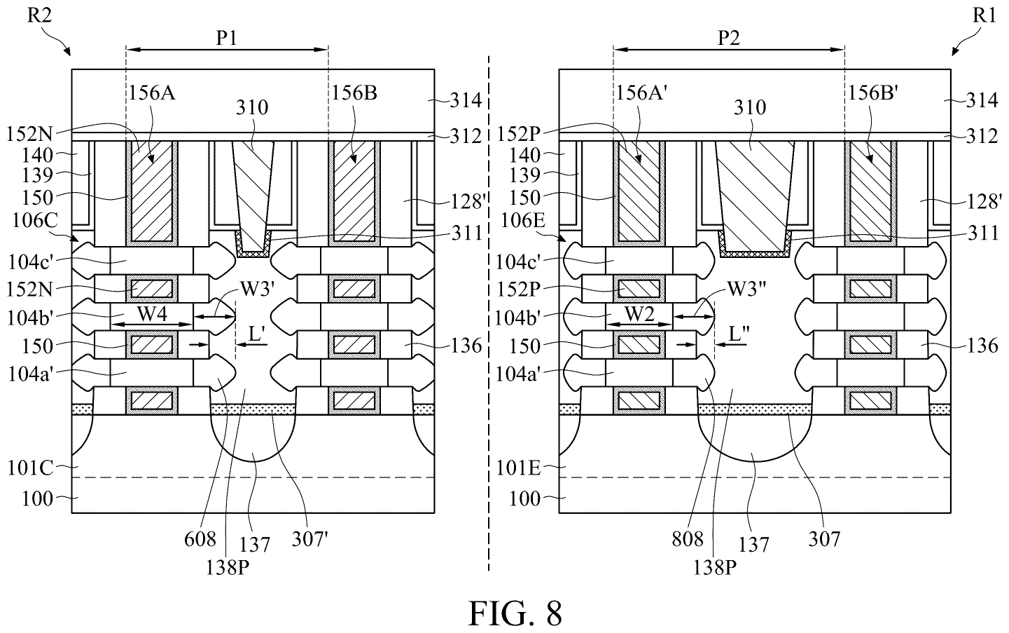

Many variations and/or modifications can be made to embodiments of the disclosure. FIG. 8 is a cross-sectional view of portions of a semiconductor device structure, in accordance with some embodiments. As shown in FIG. 8, different devices are formed in regions R2 and R4 of a semiconductor device structure. In some embodiments, a structure that is the same as or similar to the left portion of the structure shown in FIG. 6 is formed in the region R2. As shown in FIG. 8, there is a gate pitch P1 between the between the metal gate stacks 156A and 156B.

In some embodiments, a structure that is the same as or similar to the right portion of the structure shown in FIG. 6 is formed in the region R4. The structure in the region R4 may be formed using similar processes that are illustrated in FIGS. 3A-3Q. In some embodiments, similar to the fin structure 106A, a fin structure 106E is formed. Multiple semiconductor nanostructures 104a′-104c′ are formed over a semiconductor fin 101E. Similar to epitaxial structures 308, epitaxial structures 808 are formed before the formation of the epitaxial structures 138P in the region R4. As shown in FIG. 8, there is a gate pitch P2 between the between the metal gate stacks 156A′ and 156B′. In some embodiments, the pitch P2 is longer than the pitch P1.

As shown in FIG. 8, in some embodiments, each of the semiconductor nanostructures 104a′-104c′ in the region R3 has the length W4 that is longer than each of the semiconductor nanostructures 104a′-104c′ in the region R4 that has the length W4. In some embodiments, separate lateral etching processes are used to pull back the semiconductor layers 104a-104c before the formation of the epitaxial structures 308 and 808. By adjusting the lateral etching of the semiconductor layers 104a-104c in different regions, the lengths of the resulting semiconductor nanostructures 104a′-104c′ can be modified accordingly to meet specific requirements.

As shown in FIG. 8, each of the epitaxial structures 808 has the width W3″. The width W3″ may be within 1 nm to about 20 nm. In some embodiments, the epitaxial structures 808 in the region R4 and the epitaxial structures 608 in the region R3 are simultaneously formed. In some embodiments, each of the epitaxial structures 608 is substantially as wide as each of the epitaxial structures 808. The width W3″ is substantially equal to the width W3′.

However, embodiments of the disclosure are not limited thereto. Many variations and/or modifications can be made to embodiments of the disclosure. In some other embodiments, the widths W3 and W3′ are different.

In some embodiments, each of the epitaxial structures 808 extends past the edges of the inner spacers 136 nearby. Each of the epitaxial structures 808 has an extrusion portion that extends into the epitaxial structure 138P nearby. In some embodiments, the epitaxial structures 138P are wrapped around the extrusion portions of the epitaxial structures 808, as shown in FIG. 8. Each of the extrusion portions of the epitaxial structures 808 has a width L″, as shown in FIG. 8. In some embodiments, the extrusion portion of each of the epitaxial structures 608 is wider than the extrusion portion of each of the epitaxial structures 808. The width L′ is wider than the width L″.

In some embodiments, the silicon-based epitaxial structure (such as the epitaxial structures 308, 408, 508, 608 and 808) help to protect the silicon germanium-based epitaxial structures (such as the epitaxial structures 138P) from being etched or damaged during the removal of the semiconductor layers 102a-102c that are also silicon germanium-based. The quality and reliability of the semiconductor device structure are improved. In addition, the diffusion of the p-type dopant, such as boron, is enhanced in the silicon-based epitaxial structures, thereby reducing resistance and improving performance.

In some embodiments, the silicon-based epitaxial structures have extrusion portions that extend past the edges of the inner spacers nearby and are surrounded by the silicon germanium-based epitaxial structure. However, embodiments of the disclosure are not limited thereto. Many variations and/or modifications can be made to embodiments of the disclosure. In some other embodiments, the silicon-based epitaxial structure does not have any extrusion portion that extends past the edges of the inner spacers nearby.

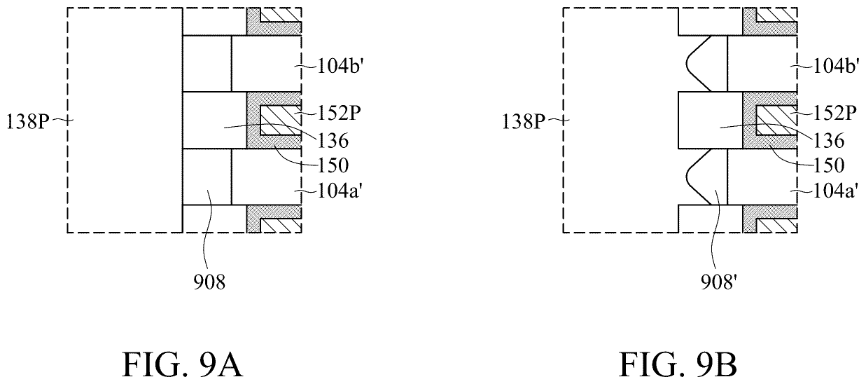

FIG. 9A is a cross-sectional view of a portion of a semiconductor device structure, in accordance with some embodiments. Similar to the epitaxial structures 308 of the embodiments illustrated in FIG. 3Q, silicon-based epitaxial structures 908 are formed adjacent to the semiconductor nanostructures 104a′ and 104b′. In some embodiments, the outer side edges of the silicon-based epitaxial structures 908 are substantially aligned with the edges of the inner spacers 136 nearby. The silicon-based epitaxial structures 908 have no extrusion portion that extends past the edges of the inner spacers 136 and enters the epitaxial structure 138P nearby.

FIG. 9B is a cross-sectional view of a portion of a semiconductor device structure, in accordance with some embodiments. Similar to the epitaxial structures 308 of the embodiments illustrated in FIG. 3Q, silicon-based epitaxial structures 908′ are formed adjacent to the semiconductor nanostructures 104a′ and 104b′. In some embodiments, the outer side edges of the silicon-based epitaxial structures 908 are curved edges that are laterally between the edges of the inner spacers 136 nearby and the side edges of the semiconductor nanostructures 104a′ and 104b′. Similar to the silicon-based epitaxial structures 908 in FIG. 9A, the silicon-based epitaxial structures 908′ has no extrusion portion that extends past the edges of the inner spacers 136 and enters the epitaxial structure 138P nearby.

Many variations and/or modifications can be made to embodiments of the disclosure. In some embodiments, there are three channel structures (such as the semiconductor nanostructures 104a′-104c′) formed between the nearby epitaxial structures 138P or 138N. However, embodiments of the disclosure are not limited thereto. Many variations and/or modifications can be made to embodiments of the disclosure. In some embodiments, the total number of semiconductor nanostructures between the nearby epitaxial structures 138P or 138N is greater than three. In some other embodiments, the total number of semiconductor nanostructures between the nearby epitaxial structures 138P or 138N is smaller than three. The total number of semiconductor nanostructures (or channel structures) between the nearby epitaxial structures 138P or 138N may be fine-tuned to meet requirements. For example, the total number of semiconductor nanostructures between the nearby epitaxial structures 138P or 138N may be between 2 and 10. The semiconductor nanostructures may have many applicable profiles. The semiconductor nanostructures may include nanosheets, nanowires, or other suitable nanostructures.

Embodiments of the disclosure form a semiconductor device structure with a silicon-based epitaxial structure formed between the channel structure and the silicon germanium-based epitaxial structure. The diffusion of the p-type dopant, such as boron, is enhanced in the silicon-based epitaxial structures, thereby reducing resistance and improving performance. The silicon-based epitaxial structure may also help to protect the silicon germanium-based epitaxial structure from being etched or damaged during the formation processes. The quality and reliability of the semiconductor device structure are greatly improved.

In accordance with some embodiments, a method for forming a semiconductor device structure is provided. The method includes forming a fin structure over a substrate, and the fin structure has multiple sacrificial layers and multiple semiconductor layers laid out in an alternating manner. The method also includes forming multiple silicon-containing epitaxial structures from edges of the semiconductor layers, and the silicon-containing epitaxial structures are p-type doped. The method further includes forming a germanium-containing epitaxial structure on the silicon-containing epitaxial structures. The germanium-containing epitaxial structure has a higher atomic concentration of germanium than that of the silicon-containing epitaxial structures. In addition, the method includes removing the sacrificial layer to release multiple semiconductor nanostructures constructed by remaining portions of the semiconductor layers. The method also includes forming a metal gate stack wrapped around each of the semiconductor nanostructures.

In accordance with some embodiments, a method for forming a semiconductor device structure is provided. The method includes forming multiple sacrificial layers and multiple semiconductor layers laid out in an alternating manner on a substrate. The method also includes partially removing the sacrificial layers and the semiconductor layers to form a recess exposing side edges of the sacrificial layers and the semiconductor layers. The method further includes forming p-type doped epitaxial structures on the side edges of the semiconductor layers and forming a germanium-containing epitaxial structure wrapped around the p-type doped epitaxial structures. The germanium-containing epitaxial structure has a higher atomic concentration of germanium than that of the p-type doped epitaxial structures. In addition, the method includes removing the sacrificial layers to release multiple semiconductor nanostructures constructed by remaining portions of the semiconductor layers and forming a metal gate stack wrapped around each of the semiconductor nanostructures.

In accordance with some embodiments, a semiconductor device structure is provided. The semiconductor device structure includes multiple channel structures stacked over a substrate and a gate stack wrapped around each of the channel structures. The semiconductor device structure also includes multiple p-type doped epitaxial structures extending from side edges of the channel structures. The semiconductor device structure further includes an epitaxial structure contacting each of the p-type doped epitaxial structures. Each of the p-type doped epitaxial structures has a higher atomic concentration of silicon than that of the epitaxial structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a fin structure over a substrate, wherein the fin structure has a plurality of sacrificial layers and a plurality of semiconductor layers laid out in an alternating manner;
forming a plurality of silicon-containing epitaxial structures from edges of the semiconductor layers, wherein the silicon-containing epitaxial structures are p-type doped;
forming a germanium-containing epitaxial structure on the silicon-containing epitaxial structures, wherein the germanium-containing epitaxial structure has a higher atomic concentration of germanium than that of the silicon-containing epitaxial structures;
removing the sacrificial layer to release a plurality of semiconductor nanostructures constructed by remaining portions of the semiconductor layers; and
forming a metal gate stack wrapped around each of the semiconductor nanostructures.

2. The method for forming a semiconductor device structure as claimed in claim 1, wherein the germanium-containing epitaxial structure is wrapped around terminal portions of the silicon-containing epitaxial structures.

3. The method for forming a semiconductor device structure as claimed in claim 1, further comprising:
partially removing the semiconductor layers to pull back the edges of the semiconductor layers before forming the silicon-containing epitaxial structures.

4. The method for forming a semiconductor device structure as claimed in claim 3, further comprising:
forming a bottom isolation structure over the substrate before the edges of the semiconductor layers are pulled back, wherein the bottom isolation structure is between the substrate and the germanium-containing epitaxial structure.

5. The method for forming a semiconductor device structure as claimed in claim 3, further comprising:
forming a plurality of inner spacers over edges of the sacrificial layers before the edges of the semiconductor layers are pulled back.

6. The method for forming a semiconductor device structure as claimed in claim 5, wherein the silicon-containing epitaxial structures extend past edges of the inner spacers, and each of the silicon-containing epitaxial structures has an extrusion portion extending into the germanium-containing epitaxial structure.

7. The method for forming a semiconductor device structure as claimed in claim 6, further comprising:
forming a plurality of second semiconductor nanostructures over the substrate, wherein each of the second semiconductor nanostructures is longer than each of the semiconductor nanostructures;
forming a plurality of second silicon-containing epitaxial structures, wherein the second silicon-containing epitaxial structures extend from edges of the second semiconductor nanostructures, and the second silicon-containing epitaxial structures are p-type doped; and
forming a second germanium-containing epitaxial structure wrapped around the second silicon-containing epitaxial structures, wherein the second germanium-containing epitaxial structure has a higher atomic concentration of germanium than that of the second silicon-containing epitaxial structure.

8. The method for forming a semiconductor device structure as claimed in claim 7, wherein each of the second silicon-containing epitaxial structures is substantially as wide as each of the silicon-containing epitaxial structures.

9. The method for forming a semiconductor device structure as claimed in claim 8, further comprising:
forming a plurality of second inner spacers over the substrate, wherein the second inner spacers extend across interfaces between the second semiconductor nanostructures and the second silicon-containing epitaxial structures, the second silicon-containing epitaxial structures extend past edges of the second inner spacers, each of the second silicon-containing epitaxial structures has a second extrusion portion extending into the second germanium-containing epitaxial structure, and the second extrusion portion is wider than the extrusion portion.

10. The method for forming a semiconductor device structure as claimed in claim 1, wherein two or more of the silicon-containing epitaxial structures are formed to merge together.

11. A method for forming a semiconductor device structure, comprising:
forming a plurality of sacrificial layers and a plurality of semiconductor layers laid out in an alternating manner on a substrate;
partially removing the sacrificial layers and the semiconductor layers to form a recess exposing side edges of the sacrificial layers and the semiconductor layers;
forming p-type doped epitaxial structures on the side edges of the semiconductor layers;
forming a germanium-containing epitaxial structure wrapped around the p-type doped epitaxial structures, wherein the germanium-containing epitaxial structure has a higher atomic concentration of germanium than that of the p-type doped epitaxial structures;
removing the sacrificial layers to release a plurality of semiconductor nanostructures constructed by remaining portions of the semiconductor layers; and
forming a metal gate stack wrapped around each of the semiconductor nanostructures.

12. The method for forming a semiconductor device structure as claimed in claim 11, further comprising:
partially removing the sacrificial layers to pull back the side edges of the sacrificial layers;
forming inner spacers covering the side edges of the sacrificial layers after the side edges of the sacrificial layers are pulled back before the p-type doped epitaxial structures are formed; and
partially removing the semiconductor layers to pull back the side edges of the semiconductor layers before the p-type doped epitaxial structures are formed on the side edges of the semiconductor layers.

13. The method for forming a semiconductor device structure as claimed in claim 12, further comprising:
forming a bottom isolation structure over the substrate after the inner spacers are formed and before the side edges of the semiconductor layers are pulled back, wherein the bottom isolation structure is between the substrate and the germanium-containing epitaxial structure after the germanium-containing epitaxial structure is formed.

14. The method for forming a semiconductor device structure as claimed in claim 11, wherein at least two of the p-type doped epitaxial structures merge together.

15. The method for forming a semiconductor device structure as claimed in claim 11, further comprising:
forming a conductive contact extending into the germanium-containing epitaxial structure, wherein the conductive contact is physically separated from the p-type doped epitaxial structures by the germanium-containing epitaxial structure.

16. A semiconductor device structure, comprising:
a plurality of channel structures stacked over a substrate;
a gate stack wrapped around each of the channel structures;
a plurality of p-type doped epitaxial structures extending from side edges of the channel structures; and
an epitaxial structure contacting each of the p-type doped epitaxial structures, wherein each of the p-type doped epitaxial structures has a higher atomic concentration of silicon than that of the epitaxial structure.

17. The semiconductor device structure as claimed in claim 16, wherein the epitaxial structure has a higher atomic concentration of germanium within a range from about 20% to about 70%, and the p-type doped epitaxial structures have a lower atomic concentration of germanium within a range from about 0% to about 5%.

18. The semiconductor device structure as claimed in claim 16, further comprising:
a plurality of inner spacers between the gate stack and the epitaxial structure, wherein the inner spacers extend across interfaces between the channel structures and the p-type doped epitaxial structures.

19. The semiconductor device structure as claimed in claim 18, wherein each of the p-type doped epitaxial structures has an inner portion and an extrusion portion extending into the epitaxial structure.

20. The semiconductor device structure as claimed in claim 19, further comprising:
a plurality of second channel structures over the substrate, wherein each of the second channel structures is longer than each of the channel structures;
a plurality of second p-type doped epitaxial structures extending from side edges of the second channel structures;
a second epitaxial structure contacting each of the second p-type doped epitaxial structures, wherein the second epitaxial structure has a higher atomic concentration of germanium than that of the second p-type doped epitaxial structures; and
a plurality of second inner spacers extending across interfaces between the second channel structures and the second p-type doped epitaxial structures, wherein each of the second p-type doped epitaxial structures has a second inner portion and a second extrusion portion extending into the second epitaxial structure, and the second protruding portion is wider than the protruding portion.
